(19) United States
(12) Patent Application Publication
(10) Pub. No.: US 2023/0292017 A1
(43) Pub. Date: Sep. 14, 2023

(54) IMAGING DEVICE

(71) Applicant: Panasonic Intellectual Property Management Co., Ltd., Osaka (JP)

(72) Inventors: MAKOTO SHOUHO, Osaka (JP); SHINICHI MACHIDA, Osaka (JP)

(21) Appl. No.: 18/317,356

(22) Filed: May 15, 2023

Related U.S. Application Data
(63) Continuation of application No. PCT/JP2021/033077, filed on Sep. 9, 2021.

(30) Foreign Application Priority Data
Nov. 30, 2020 (JP) 2020-199139

(51) Int. Cl. H04N 25/532; H04N 25/77; H04N 25/709

(52) U.S. Cl. CPC H04N 25/532; H04N 25/77; H04N 25/709

(57) ABSTRACT

An imaging device includes a photoelectric conversion layer, a counter electrode, a first electrode, a second electrode, a first transfer gate, a second transfer gate, a first amplification transistor, and a second amplification transistor. The first transistor outputs a signal corresponding to the potential of the first gate in a first readout period in which the first transfer gate suppresses transfer of signal charges. The first readout period includes a first period in which the second transfer gate allows transfer of signal charges. The second transistor outputs a signal corresponding to the potential of the second gate in a second readout period in which the second transfer gate suppresses transfer of signal charges. The second readout period includes a second period in which the first transfer gate allows transfer of signal charges.

### BACKGROUND

### 1. Technical Field

The present disclosure relates to an imaging device.

### 2. Description of the Related Art

Imaging sensors using photoelectric conversion are conventionally known. For example, complementary metal oxide semiconductor (CMOS)-type imaging sensors including photodiodes are widely used. CMOS-type imaging sensors are characterized by low power consumption and individually accessible pixels. CMOS-type imaging sensors generally employ a so-called rolling shutter as a method to read signals. The rolling shutter is a technique of sequentially performing the exposure and readout of signal charges in the pixel array on a row-by-row basis.

The rolling shutter operation starts and ends the exposure at different times for different rows of the pixel array. Capturing an image of a rapidly moving object using the rolling shutter sometimes produces a distorted image of the object, or capturing an image with a flash sometimes yields differences in brightness across the image. In the light of such circumstances, there is a demand for a so-called global shutter, which starts and ends the exposure at the same time for all the pixels in the pixel array.

For example, U.S. Patent Application Publication No. 2007/0013798 discloses a CMOS-type image sensor capable of performing the global shutter operation. According to the technique disclosed in U.S. Patent Application Publication No. 2007/0013798, each of the plural pixels is provided with a transfer transistor and a charge accumulation unit (a capacitor or a diode). In each pixel, the charge accumulation unit is coupled to a photodiode through the transfer transistor.

Japanese Unexamined Patent Application Publication No. 2016-63165 discloses an imaging element that includes an accumulation electrode facing a photoelectric conversion layer and a semiconductor layer with an insulating layer interposed therebetween. The technique disclosed in Japanese Unexamined Patent Application Publication No. 2016-63165 changes the voltage of the accumulation electrode to accumulate signal charges in the photoelectric conversion layer and the semiconductor layer and transfer the signal charges to a pixel electrode at a predetermined timing.

### SUMMARY

One non-limiting and exemplary embodiment provides an imaging device that includes a global shutter function and has less dead time in exposure.

In one general aspect, the techniques disclosed here feature an imaging device including: a photoelectric conversion layer that converts light to signal charges; a counter electrode that applies bias voltage to the photoelectric conversion layer; a first electrode and a second electrode that are spaced from each other and collect the signal charges generated in the photoelectric conversion layer; a first transfer gate that controls transfer of the signal charges from the photoelectric conversion layer to the first electrode; a second transfer gate that controls transfer of the signal charges from the photoelectric conversion layer to the second electrode; a first amplification transistor that includes a first gate electrically coupled to the first electrode; and a second amplification transistor that includes a second gate electrically coupled to the second electrode, in which the first transfer gate suppresses the transfer of the signal charges in a first readout period in which the first transistor outputs a signal corresponding to the potential of the first gate, the second transfer gate suppresses the transfer of the signal charges in a second readout period in which the second transistor outputs a signal corresponding to the potential of the second gate, the first readout period includes a first period in which the second transfer gate allows the transfer of the signal charges, and the second readout period includes a second period in which the first transfer gate allows the transfer of the signal charges.

Comprehensive or specific aspects may be implemented as an element, a device, a module, a system, or a method. Comprehensive or specific aspects may also be implemented as any selective combination of the element, the device, an apparatus, the module, the system, and the method.

According to the imaging device of the present disclosure, it is possible to provide the global shutter function and reduce dead time in exposure.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram illustrating a configuration example of an imaging device according to Embodiment 1;

FIG. 2A is a diagram illustrating a circuit configuration example of a pixel of the imaging device according to Embodiment 1;

FIG. 2B is a plan view illustrating the layout of electrodes of a photoelectric converter of the imaging device according to Embodiment 1;

FIG. 3 is a diagram illustrating a sectional structure example of main part of a pixel of the imaging device according to Embodiment 1;

FIG. 4 is a timing chart illustrating an operation example of a pixel of the imaging device according to Embodiment 1;

FIG. 5 is a diagram illustrating a potential profile of a pixel in each period in FIG. 4 according to Embodiment 1;

FIG. 6 is a timing chart illustrating an operation example of a pixel of the imaging device according to Embodiment 1;

FIG. 7 is a timing chart illustrating an operation example of a pixel of an imaging device according to Embodiment 2;

FIG. 8 is a diagram illustrating a circuit configuration example of a pixel of an imaging device according to Embodiment 3;

FIG. 9 is a timing chart illustrating an operation example of a pixel of an imaging device according to Embodiment 4;

FIG. 10 is a diagram illustrating a potential profile of a pixel in each period in FIG. 9 according to Embodiment 4;

FIG. 11 is a timing chart illustrating an operation example of a pixel of an imaging device according to Embodiment 5;

FIG. 12 is a diagram illustrating a potential profile of a pixel in each period in FIG. 11 according to Embodiment 5;

FIG. 13 is a diagram illustrating a circuit configuration example of a pixel of an imaging device according to Embodiment 6;

FIG. 14 is a timing chart illustrating an operation example of a pixel of the imaging device according to Embodiment 6;

FIG. 15 is a diagram illustrating a potential profile of a pixel in each period in FIG. 14 according to Embodiment 6;

FIG. 16 is a timing chart illustrating an operation example of a pixel of an imaging device according to Embodiment 7;

FIG. 17 is a diagram illustrating a potential profile of a pixel of the imaging device according to Embodiment 7;

FIG. 18 is a diagram illustrating a sectional structure example of a main portion of a pixel of an imaging device according to Embodiment 8;

FIG. 19 is a timing chart illustrating an operation example of a pixel of the imaging device according to Embodiment 8;

FIG. 20A is a diagram illustrating a circuit configuration example of a pixel of an imaging device according to Embodiment 9;

FIG. 20B is a diagram illustrating another circuit configuration example of a pixel of the imaging device according to Embodiment 9;

FIG. 21 is a diagram illustrating a modification of the circuit configuration of a pixel of the imaging device according to Embodiment 9; and

FIG. 22 is a diagram illustrating another modification of the circuit configuration of a pixel of the imaging device according to Embodiment 9.

### DETAILED DESCRIPTIONS

### Underlying Knowledge Forming Basis of the Present Disclosure

The techniques of U.S. Patent Application Publication No. 2007/0013798 and Japanese Unexamined Patent Application Publication No. 2016-63165 implement a global shutter. However, signal charges generated in the photoelectric conversion layer in the readout period of the rolling operation cannot be used, resulting in wasted time. In other words, wasted time, that is, dead time in exposure occurs in the signal charge readout period.

In order to remove such wasted time, the inventors of the present disclosure have intensively considered configurations that are able to effectively use signal charges generated in the readout period. As a result, the inventors have achieved a new technology of the present disclosure that efficiently provides a global shutter function and is able to reduce the dead time in exposure.

An imaging device according to an aspect of the present disclosure includes: a plurality of pixels, each of the plurality of pixels including a photoelectric conversion layer that converts light to signal charges; a counter electrode that applies bias voltage to the photoelectric conversion layer; a first electrode and a second electrode that are spaced from each other and collect the signal charges generated in the photoelectric conversion layer; a first transfer gate that controls transfer of the signal charges to the first electrode; a second transfer gate that controls transfer of the signal charges to the second electrode; a first amplification transistor that includes a first gate electrically coupled to the first electrode; and a second amplification transistor that includes a second gate electrically coupled to the second electrode, in which the first transfer gate suppresses the transfer of the signal charges to the first electrode in a first readout period in which the first amplification transistor outputs a signal corresponding to the potential of the first gate, the second transfer gate suppresses the transfer of the signal charges to the second electrode in a second readout period in which the second amplification transistor outputs a signal corresponding to the potential of the second gate, the first readout period includes a first period in which the second transfer gate allows the transfer of the signal charges to the second electrode, and the second readout period includes a second period in which the first transfer gate allows the transfer of the signal charges to the first electrode.

According to the aforementioned aspect, the operation of reading the signal charges collected by the first electrode and the operation of the second electrode collecting the signal charges by exposure and transfer are performed in parallel. The operation of reading signal charges collected by the second electrode and the operation of the first electrode collecting the signal charges by exposure and transfer are performed in parallel. This can implement the global shutter function and reduce the dead time in exposure.

The first period may have the same length as the first readout period, and the second period may have the same length as the second readout period.

According to the aforementioned configuration, the second transfer gate transfers the signal charges to the second electrode throughout the entire first readout period. The first transfer gate transfers the signal charges to the first electrode throughout the entire second readout period. Even when a lot of signal charges are generated due to intense light, therefore, an overflow from the first transfer gate or the second transfer gate of the generated signal charges can be suppressed.

The first readout period and the second readout period may be continuously alternated.

This enables continuous imaging with reduced dead time in exposure.

The first readout period may include a third period immediately preceding the first period, in the third period, the second transfer gate may suppress the transfer of the signal charges, the second readout period may include a fourth period immediately preceding the second period, and in the fourth period, the first transfer gate may suppress the transfer of the signal charges.

According to the aforementioned configuration, signal charges are once accumulated between the first transfer gate and the second transfer gate in the third period and then transferred to the second electrode in the first period. Furthermore, signal charges are once accumulated between the first transfer gate and the second transfer gate in the fourth period and then transferred to the first electrode in the second period. Such a configuration also implements the global shutter function and reduces the dead time in exposure.

Each of the plurality of pixels may further include a first charge accumulator that is electrically coupled to the first electrode and accumulates the signal charges collected by the first electrode, and a second charge accumulator that is electrically coupled to the second electrode and accumulates the signal charges collected by the second electrode.

The first charge accumulator may have a smaller capacitance than the second charge accumulator.

According to the aforementioned configuration, the difference in capacitance between the first charge accumulator and the second charge accumulator allows the detection signals outputted from the first amplification transistor and the second amplification transistor to have different sensitivities. Combining these detection signals, for example, can expand the dynamic range.

Each of the plurality of pixels may further include a capacitor coupled to the second electrode.

According to the aforementioned configuration, the first amplification transistor and the second amplification transistor can detect signal charges with different sensitivities. Combining these detection signals, for example, can expand the dynamic range.

Each of the plurality of pixels may further include a charge accumulation electrode which is positioned between the first transfer gate and the second transfer gate and faces the counter electrode with the photoelectric conversion layer interposed between the charge accumulation electrode and the counter electrode.

The aforementioned configuration can form an electric field between the counter electrode and the charge accumulation electrode. The signal charges generated in the photoelectric conversion layer can thereby move toward the charge accumulation electrode.

Each of the plurality of pixels may further include a semiconductor layer that is positioned between the photoelectric conversion layer and each of the first electrode and the second electrode.

The semiconductor layer may have a higher charge mobility than the photoelectric conversion layer.

The aforementioned configuration can accelerate the transfer by the first transfer gate and also can accelerate the transfer by the second transfer gate.

The first readout period may have the same length as the second readout period.

The aforementioned configuration can reduce or remove the dead time in exposure.

The first readout period may have the same length as a vertical synchronization period.

According to the aforementioned configuration, alternating the first readout period and the second readout period at every vertical synchronization period, that is, at every frame period can reduce the dead time in exposure.

The second readout period may have a greater length than the first readout period.

According to the aforementioned configuration, the second readout period, that is, the exposure time in which signal charges to be collected to the first electrode are generated is longer than the first readout period, that is, the exposure time in which signal charges to be collected to the second electrode are generated. The detection signal outputted from the first amplification transistor therefore has a higher sensitivity than the detection signal outputted from the second amplification transistor. Combining these detection signals, for example, can expand the dynamic range.

The imaging device may further include a voltage supply circuit coupled to the counter electrode, in which the voltage supply circuit may supply a first voltage to the counter electrode in the first readout period and may supply a second voltage to the counter electrode in the second readout period, the second voltage being different from the first voltage.

According to the aforementioned configuration, the quantum efficiency of the photoelectric conversion layer can be varied depending on the voltage supplied to the counter electrode.

The photoelectric conversion layer may include a first photoelectric conversion layer that is sensitive to light having a first range of wavelength, and a second photoelectric conversion layer that is sensitive to light having a second range of wavelength that is different from the first range of wavelength.

According to the aforementioned configuration, changing the voltage supplied to the counter electrode can vary the spectral sensitivity characteristic of the photoelectric conversion layer. This enables switching between imaging sensitive to infrared light and imaging sensitive to visible light, for example.

Each of the plurality of pixels may further include a first feedback circuit that provides negative feedback of the potential of the first electrode to the first electrode.

According to the aforementioned configuration, operating the first feedback circuit during the operation to reset the potential of the first electrode can reduce the influence of reset noise.

Each of the plurality of pixels may further include a second feedback circuit that provides negative feedback of the potential of the second electrode to the second electrode.

According to the aforementioned configuration, operating the second feedback circuit during the operation to reset the potential of the second electrode can reduce the influence of reset noise.

An imaging device according to another aspect of the present disclosure includes a plurality of pixels, each of the plurality of pixels including a photoelectric conversion layer that converts light to signal charges; a counter electrode that applies bias voltage to the photoelectric conversion layer; a first electrode and a second electrode that are spaced from each other and collect the signal charges generated in the photoelectric conversion layer; a first transfer gate that controls transfer of the signal charges to the first electrode; a second transfer gate that controls transfer of the signal charges to the second electrode; a first charge accumulator electrically coupled to the first electrode; and a second charge accumulator electrically coupled to the second electrode. The second charge accumulator has a greater capacitance than the first charge accumulator.

According to the aforementioned configuration, the difference in capacitance between the first charge accumulator and the second charge accumulator allows detection signals outputted from a first amplification transistor and a second amplification transistor to have different sensitivities. Combining these detection signals, for example, can expand the dynamic range.

The second charge accumulator may include a capacitor.

The aforementioned configuration allows detection signals outputted from the first amplification transistor and the second amplification transistor to have different sensitivities. Combining these detection signals, for example, can expand the dynamic range.

Each of the plurality of pixels may further include a first amplification transistor including a first gate electrically coupled to the first electrode; and a second amplification transistor including a second gate electrically coupled to the second electrode.

The aforementioned configuration provides the global shutter function and reduces the dead time in exposure.

Alternatively, each of the plurality of pixels may include a first amplification transistor including a first gate electrically coupled to the second electrode, and the first gate may be electrically coupled to the second electrode through a first switch.

The aforementioned configuration provides detection signals having two different sensitivities between when the first gate is electrically coupled to the second electrode by the first switch and when the first gate is electrically decoupled from the second electrode by the first switch. Combining these detection signals can expand the dynamic range.

Each pixel may further include a feedback circuit that provides negative feedback of the potential of the first charge accumulator to the first charge accumulator.

According to the aforementioned configuration, operating the feedback circuit during the operation to reset the potential of the first charge accumulator can reduce the influence of reset noise.

An imaging device according to still another aspect of the present disclosure includes a plurality of pixels, each of the plurality of pixels including a photoelectric conversion layer that converts light to signal charges; a counter electrode that applies bias voltage to the photoelectric conversion layer; a first electrode that collects the signal charges generated in the photoelectric conversion layer; a first transfer gate that controls transfer of the signal charges to the first electrode; and a feedback circuit that provides negative feedback of the potential of the first electrode to the first electrode.

According to the aforementioned configuration, operating the feedback circuit during the operation to reset the potential of the first electrode can reduce the influence of reset noise.

All or part of the aforementioned comprehensive or specific aspects may be implemented by a system, a method, an integrated circuit, a computer program, or a computer-readable recording medium such as a CD-ROM and may be implemented by any combination of a system, a method, an integrated circuit, a computer program, and a recording medium.

Hereinafter, embodiments of the present disclosure will be described with reference to the drawings.

All of the embodiments described below illustrate comprehensive or specific examples. Numerical values, shapes, materials, constituent components, positions and coupling manners of constituent components, steps, sequence of steps, and the like indicated in the following embodiments are illustrated by way of examples and will not limit the present disclosure. The constituent components that are included in the following embodiments but are not included in the independent claims are described as optional constituent components.

In some cases, unnecessarily detailed description is omitted. For example, detailed description of well-known matters and repeated description about substantially identical configurations are omitted in some cases. This is to prevent the following description from being unnecessarily redundant and to facilitate understanding by those skilled in the art. The accompanying drawings and the following description are to allow those skilled in the art to sufficiently understand the present disclosure and will not limit the subjects described in claims.

All the numerical values described below are illustrated for specifically describing the present disclosure, and the present disclosure are not limited by the illustrated numerical values. Furthermore, connection relationships between constituent components are illustrated to specifically describe the present disclosure, and the connection relationships implementing the functions of the present disclosure are not limited to those illustrated below.

Each drawing is schematic and is thus not always illustrated precisely. Each drawing therefore does not have the same scale, for example.

In the specification, terms, such as parallel or orthogonal, indicating the relationship between elements, terms indicating the shape of elements, and numerical ranges are not only expressions representing exact meanings but also expressions representing a substantially equivalent range, including a difference of several percent, for example.

In the specification, the terms “above” and “below” do not indicate the up direction (vertically up) and the down direction (vertically down) in an absolute space recognition and are used as terms specified depending on the relative positional relationship based on the stacking sequence of a stacking structure. Furthermore, the terms “above” and “below” are applied not only to the situation where two constituent components are spaced with another constituent component located between the two constituent components but also to the situation where two constituent components are arranged in close contact so as to abut on each other.

### Embodiment 1

### Entire Configuration of Imaging Device

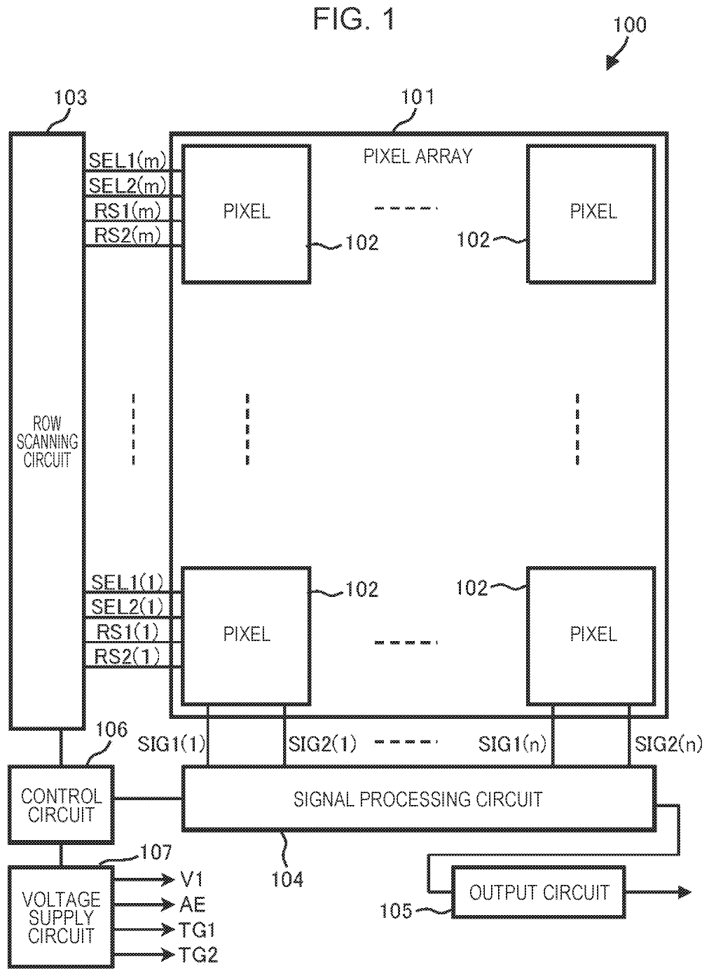

FIG. 1 is a diagram illustrating a configuration example of an imaging device according to Embodiment 1. An imaging device 100 illustrated in FIG. 1 includes a pixel array 101. The pixel array 101 includes plural pixels 102.

Each of the plural pixels 102 includes a photoelectric converter that converts incoming light into charges; and two readout circuits. That is, in each pixel 102, one photoelectric converter is provided with two readout circuits. The plural pixels 102 are two-dimensionally arrayed in a semiconductor substrate, for example, so that the pixel array 101 forms an imaging area. In this example, the pixels 102 are arrayed in a matrix with m rows and n columns. The center of each pixel 102 is positioned on a lattice point of a square lattice. Certainly, the arrangement of the pixels 102 is not limited to the illustrated example. For example, the plural pixels 102 may be arranged so that the center of each pixel 102 be positioned on a lattice point of a triangle lattice, a hexagonal lattice, or the like.

In the configuration illustrated in FIG. 1, peripheral circuits include a row scanning circuit 103, a signal processing circuit 104, an output circuit 105, a control circuit 106, and a voltage supply circuit 107. The peripheral circuits may be arranged on a semiconductor substrate in which the pixel array 101 is formed, or some of the peripheral circuits may be arranged on another substrate.

The row scanning circuit 103 is also referred to as a vertical scanning circuit. The row scanning circuit 103 selects the plural pixels 102, which are arranged in m rows and n columns, on a row-by-row basis to execute, for example, readout of signal voltage and reset of charge accumulation nodes in the pixels 102. The row scanning circuit 103 supplies selection control signals SEL1 and SEL2 and reset control signals RS1 and RS2 to each row of the pixels 102.

FIG. 1 schematically illustrates connections between each pixel 102 and the row scanning circuit 103. The number of control lines arranged for each row of the plural pixels 102 is not limited to four. In the later-described embodiments, for example, the row scanning circuit 103 may be coupled to control lines that are provided corresponding to each row of the plural pixels 102 for supplying transfer gate signals TG1 and TG2.

The signal processing circuit 104 is coupled to pairs of vertical signal lines SIG1(1) and SIG2(1), SIG1(n) and SIG2(n), which are provided corresponding to the respective columns of the plural pixels 102. Outputs from the pixels 102 are selected by the row scanning circuit 103 on a row-by-row basis to be read by the signal processing circuit 104 through the vertical signal lines SIG1(1), SIG2(1), SIG1(n), and SIG2(n). The signal processing circuit 104 performs for output signals read from the pixels 102, noise suppression signal processing represented by correlated double sampling, analogue-digital conversion, and other processing. The output from the signal processing circuit 104 is supplied outside the imaging device 100 through the output circuit 105.

The control circuit 106 receives instruction data, clock, and the like given from a source external to the imaging device 100, for example, to control the entire imaging device 100. The control circuit 106 typically includes a timing generator and supplies drive signals to the row scanning circuit 103, signal processing circuit 104, voltage supply circuit 107, and the like.

The voltage supply circuit 107 supplies bias voltage V1, voltage AE, and the transfer gate signals TG1 and TG2 to all the pixels 102 under control of the control circuit 106.

### Configuration of Pixel

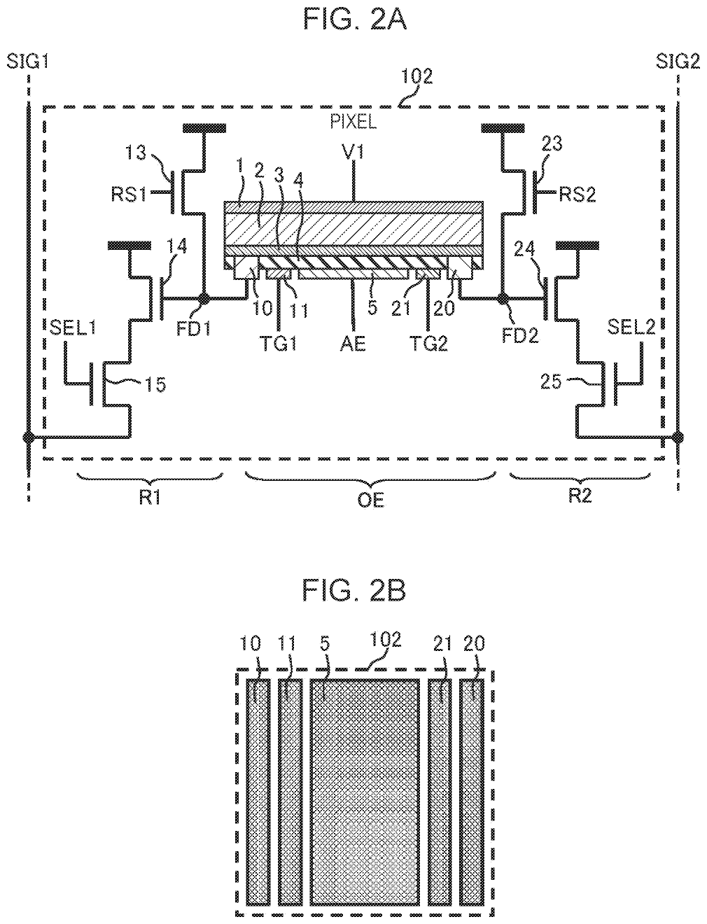

FIG. 2A is a diagram illustrating a circuit configuration example of a pixel 102 according to Embodiment 1. As illustrated in FIG. 2A, the pixel 102 is roughly composed of three parts, including a photoelectric converter OE and readout circuits R1 and R2. The photoelectric converter OE in FIG. 2A illustrates a schematic sectional configuration.

The photoelectric converter OE in FIG. 2A includes a counter electrode 1, a photoelectric conversion layer 2, a semiconductor layer 3, an insulating layer 4, an electric charge accumulation electrode 5, a first electrode 10, a first transfer gate 11, a second electrode 20, and a second transfer gate 21.

The counter electrode 1 applies the bias voltage V1 to the photoelectric conversion layer 2. The counter electrode 1 is a transparent electrode made of ITO, for example, and is also referred to as an upper electrode. On the counter electrode 1, a sealing film, a color filter, or a micro-lens may be arranged, which are not illustrated in FIG. 2A. Instead of or in addition to the color filter, an infrared transparent filter may be arranged.

The photoelectric conversion layer 2 converts incoming light from the counter electrode 1 side into signal charges.

The semiconductor layer 3, which is also referred to as a channel layer, has a higher charge mobility than the photoelectric conversion layer 2 to facilitate movement of charges.

The insulating layer 4 insulates the semiconductor layer 3 from the charge accumulation electrode 5, first transfer gate 11, and second transfer gate 21.

The charge accumulation electrode 5 moves signal charges generated in the photoelectric conversion layer 2 to the semiconductor layer 3 by the potential difference between the charge accumulation electrode 5 and the counter electrode 1 to accumulate the signal charges in the vicinity of the interface with the insulating layer 4. The quantum efficiency of the photoelectric conversion layer 2 can be adjusted depending on the potential difference between the counter electrode 1 and the charge accumulation electrode 5.

The first electrode 10 is also referred to as a first pixel electrode. The first electrode 10 penetrates the insulating layer 4 and is in contact with the semiconductor layer 3. Signal charges move toward the first electrode 10 within the semiconductor layer 3 due to an electric field generated by the potential difference between the charge accumulation electrode 5 and the first electrode 10. The first electrode 10 collects the signal charges having moved within the semiconductor layer 3. The first electrode 10 is coupled to a first charge accumulator FD1, and the signal charges collected by the first electrode 10 are accumulated in the first charge accumulator FD1.

The first transfer gate 11 receives the transfer gate signal TG1. The first transfer gate 11 controls transfer of signal charges within the semiconductor layer 3 depending on the voltage value of the transfer gate signal TG1. For example, when the transfer gate signal TG1 is high, the transfer channel above the first transfer gate 11 is conducting, and signal charges are transferred to the first electrode 10. When the transfer gate signal TG1 is low, the transfer channel above the first transfer gate 11 is non-conducting, and no signal charges are transferred to the first electrode 10. When the transfer gate signal TG1 is middle, the transfer channel above the first transfer gate 11 is semi-conducting. Only when the amount of signal charges exceeds a predetermined amount, the excess signal charges are transferred to the first electrode 10.

When the transfer gate signal TG1 is high, the first transfer gate 11 is supplied with a voltage forming an electric field that allows signal charges above the charge accumulation electrode 5 to move to the first electrode 10. When signal charges are holes, for example, the voltage applied to the first transfer gate 11 when the transfer gate signal TG1 is high may be lower than the voltage of the charge accumulation electrode 5 and higher than the voltage of the first electrode 10. When signal charges are electrons, for example, the voltage applied to the first transfer gate 11 when the transfer gate signal TG1 is high may be higher than the voltage of the charge accumulation electrode 5 and lower than the voltage of the first electrode 10.

When the transfer gate signal TG1 is low, the first transfer gate 11 is supplied with a voltage forming an electric field that provides a barrier against movement of signal charges above the charge accumulation electrode 5 to the first electrode 10. When signal charges are holes, for example, the voltage applied to the first transfer gate 11 when the transfer gate signal TG1 is low may be higher than the voltage of the charge accumulation electrode 5. When signal charges are electrons, for example, the voltage applied to the first transfer gate 11 when the transfer gate signal TG1 is low may be lower than the voltage of the charge accumulation electrode 5.

When the transfer gate signal TG1 is middle, the first transfer gate 11 is supplied with a voltage forming an electric field that allows the excess signal charges beyond the predetermined amount above the charge accumulation electrode 5 to move to the first electrode 10. When signal charges are holes, for example, the voltage applied to the first transfer gate 11 when the transfer gate signal TG1 is middle may be higher than the voltage of the charge accumulation electrode 5 and lower than the voltage applied when the transfer gate signal TG1 is low. When signal charges are electrons, for example, the voltage applied to the first transfer gate 11 when the transfer gate signal TG1 is middle may be lower than the voltage of the charge accumulation electrode 5 and higher than the voltage applied when the transfer gate signal TG1 is low.

The second electrode 20 is also referred to as a second pixel electrode. The second electrode 20 penetrates the insulating layer 4 and is in contact with the semiconductor layer 3. Signal charges move toward the second electrode 20 within the semiconductor layer 3 due to an electric field generated by the potential difference between the charge accumulation electrode 5 and the second electrode 20. The second electrode 20 collects signal charges having moved within the semiconductor layer 3. The second electrode 20 is coupled to a second charge accumulator FD2, and the signal charges collected by the second electrode 20 are accumulated in the second charge accumulator FD2.

The second transfer gate 21 receives the transfer gate signal TG2. The second transfer gate 21 controls transfer of signal charges within the semiconductor layer 3 depending on the voltage value of the transfer gate signal TG2. For example, when the transfer gate signal TG2 is high, the transfer channel above the second transfer gate 21 is conducting, and signal charges are transferred to the second electrode 20. When the transfer gate signal TG2 is low, the transfer channel above the second transfer gate 21 is non-conducting, and no signal charges are transferred to the second electrode 20. When the transfer gate signal TG2 is middle, the transfer channel above the second transfer gate 21 is semi-conducting. Only when the amount of signal charges exceeds a predetermined amount, the excess signal charges are transferred to the second electrode 20.

When the transfer gate signal TG2 is high, the second transfer gate 21 is supplied with a voltage forming an electric field that allows signal charges above the charge accumulation electrode 5 to move to the second electrode 20. When signal charges are holes, for example, the voltage applied to the second transfer gate 21 when the transfer gate signal TG2 is high may be lower than the voltage of the charge accumulation electrode 5 and higher than the voltage of the second electrode 20. When signal charges are electrons, for example, the voltage applied to the second transfer gate 21 when the transfer gate signal TG2 is high may be higher than the voltage of the charge accumulation electrode 5 and lower than the voltage of the second electrode 20.

When the transfer gate signal TG2 is low, the second transfer gate 21 is supplied with a voltage forming an electric field that provides a barrier against movement of signal charges above the charge accumulation electrode 5 to the second electrode 20. When signal charges are holes, for example, the voltage applied to the second transfer gate 21 when the transfer gate signal TG2 is low may be higher than the voltage of the charge accumulation electrode 5. When signal charges are electrons, for example, the voltage applied to the second transfer gate 21 when the transfer gate signal TG2 is low may be lower than the voltage of the charge accumulation electrode 5.

When the transfer gate signal TG2 is middle, the second transfer gate 21 is supplied with a voltage forming an electric field that allows excess signal charges beyond the predetermined amount among the signal charges above the charge accumulation electrode 5 to move to the second electrode 20. When signal charges are holes, for example, the voltage applied to the second transfer gate 21 when the transfer gate signal TG2 is middle may be higher than the voltage of the charge accumulation electrode 5 and lower than the voltage applied when the transfer gate signal TG2 is high. When signal charges are electrons, for example, the voltage applied to the second transfer gate 21 when the transfer gate signal TG2 is middle may be lower than the voltage of the charge accumulation electrode 5 and higher than the voltage applied when the transfer gate signal TG2 is high.

The photoelectric converter OE may include shields to inhibit light from being incident on portions in the photoelectric conversion layer 2 above the first electrode 10 and second electrode 20. This can reduce generation of signal charges not controlled by the first and second transfer gates 11 and 21, thus reducing noise.

The readout circuit R1 of FIG. 2A outputs to the vertical signal line SIG1, a signal corresponding to the amount of signal charges accumulated in the first charge accumulator FD1. The readout circuit R1 resets signal charges accumulated in the first charge accumulator FD1. The readout circuit R1 includes the first charge accumulator FD1, a first reset transistor 13, a first amplification transistor 14, and a first selection transistor 15.

The first charge accumulator FD1 is electrically coupled to the first electrode 10 and accumulates signal charges transferred from the first electrode 10. The first charge accumulator FD1 may include a diffusion layer. The first charge accumulator FD1 may include a capacitor. In the following description, the first charge accumulator FD1 is sometimes referred to as FD1.

The first reset transistor 13 resets the first charge accumulator FD1 to a reference potential according to the reset control signal RS1.

The first amplification transistor 14 amplifies the voltage corresponding to the amount of signal charges accumulated in the first charge accumulator FD1 and outputs the amplified voltage to the vertical signal line SIG1 through the first selection transistor 15. The first amplification transistor 14 constitutes a source follower circuit in conjunction with a current source provided for the vertical signal line SIG1. The first selection transistor 15 serves as a switch to couple the first amplification transistor 14 to the vertical signal line SIG1 according to the selection control signal SELL

The readout circuit R2 of FIG. 2A is a circuit to output to the vertical signal line SIG2, signal charges accumulated in the second charge accumulator FD2 as a voltage corresponding to the amount of signal charges. The readout circuit R2 includes the second charge accumulator FD2, a second reset transistor 23, a second amplification transistor 24, and a second selection transistor 25.

The second charge accumulator FD2 is electrically coupled to the second electrode 20 and accumulates signal charges transferred from the second electrode 20. The second charge accumulator FD2 may include a diffusion layer. The second charge accumulator FD2 may include a capacitor. In the following description, the second charge accumulator FD2 is sometimes referred to as FD2.

The second reset transistor 23 resets the second charge accumulator FD2 to a reference potential according to the reset control signal RS2.

The second amplification transistor 24 amplifies the voltage corresponding to the amount of signal charges accumulated in the second charge accumulator FD2 and outputs the amplified voltage to the vertical signal line SIG2 through the second selection transistor 25. The second amplification transistor 24 constitutes a source follower circuit in conjunction with a current source provided for the vertical signal line SIG2. The second selection transistor 25 serves as a switch to couple the second amplification transistor 24 to the vertical signal line SIG2 according to the selection control signal SEL2.

Next, a layout example of the electrodes and the like in lower part of the photoelectric converter OE will be described.

FIG. 2B is a plan view illustrating the layout of the electrodes in lower part of the photoelectric converter OE of the imaging device according to Embodiment 1. The dashed line in FIG. 2B indicates the outline of a pixel 102. The charge accumulation electrode 5 is disposed at the center of the pixel 102 when viewed in plan. As illustrated in FIG. 2B, the charge accumulation electrode 5 is rectangular.

The first transfer gate 11 and the second transfer gate 21 are arranged with the charge accumulation electrode 5 interposed therebetween when viewed in plan. The first transfer gate 11 and the second transfer gate 21 are elongated and rectangular.

The first electrode 10 and the second electrode 20 are arranged with the charge accumulation electrode 5 and the first and second transfer gates 11 and 21 interposed therebetween when viewed in plan. The first and second electrodes 10 and 20 are elongated and rectangular.

Next, a configuration example of a pixel 102 will be described in more detail.

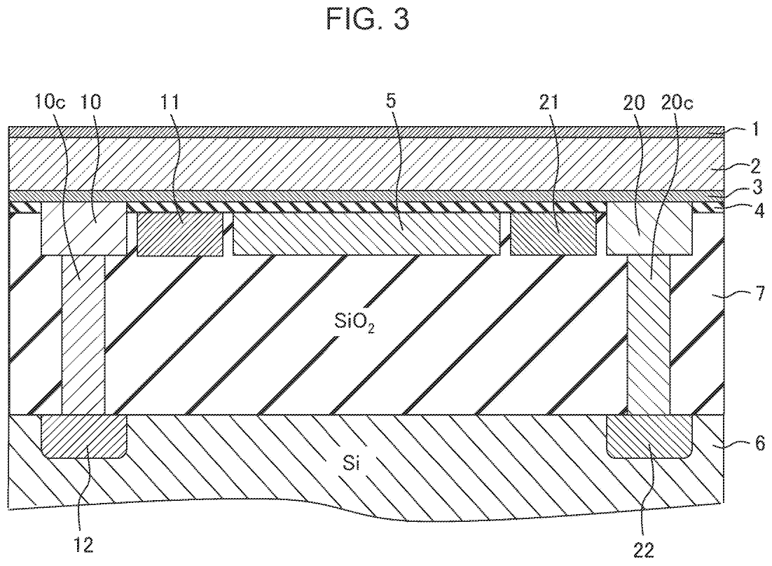

FIG. 3 is a diagram illustrating a sectional structure example of main part of a pixel 102 of the imaging device according to Embodiment 1. As illustrated in FIG. 3, the pixel 102 has a structure in which an insulating layer 7, the insulating layer 4, the semiconductor layer 3, the photoelectric conversion layer 2, and the counter electrode 1 are stacked on a semiconductor substrate 6 in this order. The pixel 102 includes the charge accumulation electrode 5, first electrode 10, first transfer gate 11, second electrode 20, and second transfer gate 21 within the insulating layer 7.

The semiconductor substrate 6 is a silicon substrate, for example. The semiconductor substrate 6 includes a first diffusion layer 12 and a second diffusion layer 22. The first diffusion layer 12 serves as part of the first charge accumulator FD1, and the second diffusion layer 22 serves as part of the second charge accumulator FD2. The first diffusion layer 12 is electrically coupled to the first electrode 10 through a contact 10c. The second diffusion layer 22 is electrically coupled to the second electrode 20 through a contact 20c.

In the semiconductor substrate 6, elements, such as transistors, constituting the readout circuits R1 and R2 are formed. Within the insulating layer 7, an interconnection layer is formed. The first transfer gate 11, the charge accumulation electrode 5, and the second transfer gate 21 receive signals through the interconnection layer.

### Timing Chart of Schematic Operation Example

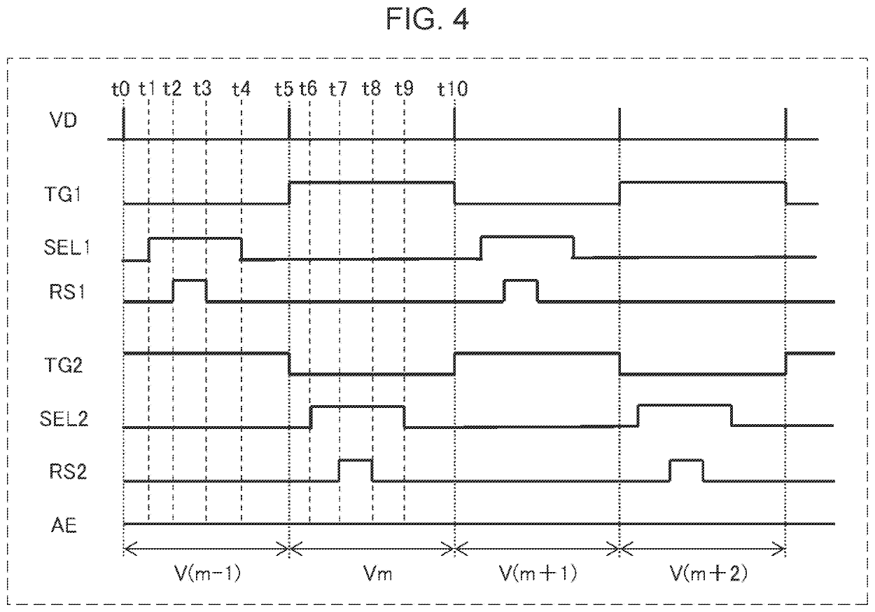

FIG. 4 is a timing chart illustrating an operation example of a pixel 102.

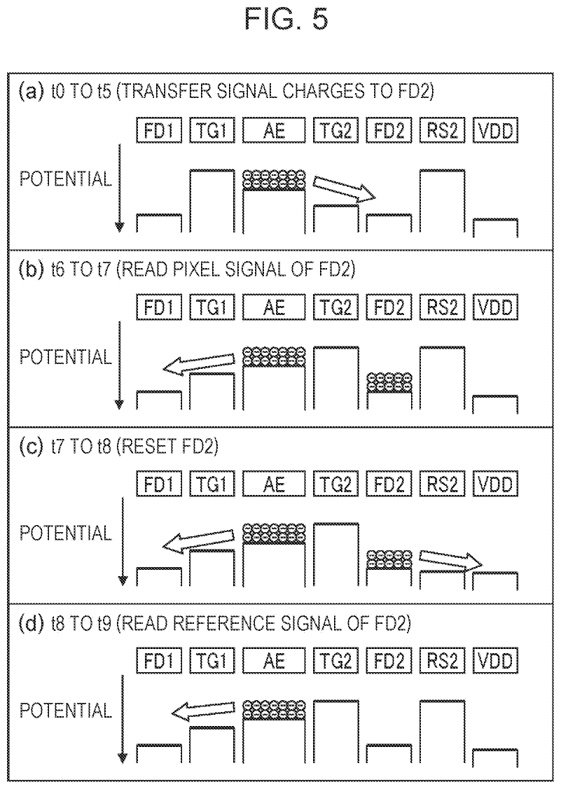

FIG. 5 is a diagram illustrating a potential profile of the pixel 102 in each period in FIG. 4.

FIG. 4 illustrates, beginning from the top, timing charts of the vertical synchronization signal VD, the transfer gate signal TG1, the selection control signal SEL1, the reset control signal RS1, the transfer gate signal TG2, the selection control signal SEL2, the reset control signal RS2, and the voltage AE of the charge accumulation electrode 5 in this order. FIG. 4 illustrates operation of only one of the m rows of the plural pixels 102 for easy understanding. Each of period V(m−1), period Vm, period V(m+1), and period V(m+2) corresponds to the vertical synchronization period, that is, one frame period.

The transfer gate signals TG1 and TG2 are high and low in a certain given frame period and are reversed to low and high in the subsequent frame period.

In the period from time t0 to time t5, that is, the period V(m−1), the transfer gate signal TG1 is set low, and the transfer gate signal TG2 is set high. In the period V(m−1) period, therefore, signal charges generated within the photoelectric conversion layer 2 are transferred to the FD2. In the period V(m−1), furthermore, the pixel signal corresponding to the amount of signal charges accumulated in the FD1 is outputted from the first amplification transistor 14 through the first selection transistor 15 to the vertical signal line SIG2. Specifically, first, the selection control signal SEL1 goes high at time t1, and the pixel signal corresponding to the amount of signal charges accumulated in the FD1 is outputted to the vertical signal line SIG1. Next, the reset control signal RS1 goes high at time t2, and the FD1 is reset to the reference potential. After the reset control signal RS1 goes low at time t3, the reference signal corresponding to the reference potential is outputted to the vertical signal line SIG1. Then the selection control signal SELL goes low at time t4, and the readout operation ends. Taking the difference between the pixel signal and reference signal outputted to the vertical signal line SIG1 provides the signal corresponding to the amount of light incident on the photoelectric converter OE during a frame period immediately preceding the period V(m−1).

In the period from time t5 to time t10, that is, the period Vm, the transfer gate signal TG1 is set high, and the transfer gate signal TG2 is set low. In the period Vm, therefore, signal charges generated within the photoelectric conversion layer 2 are transferred to the FD1. In the period Vm, furthermore, the pixel signal corresponding to the amount of signal charges accumulated in the FD2 is outputted from the second amplification transistor 24 through the second selection transistor 25 to the vertical signal line SIG2. Specifically, first, the selection control signal SEL2 goes high at time t6, and the pixel signal corresponding to the amount of signal charges accumulated in the FD2 is outputted to the vertical signal line SIG2. Next, the reset control signal RS2 goes high at time t7, and the FD2 is reset to the reference potential. After the reset control signal RS2 goes low at time t8, the reference signal corresponding to the reference potential is outputted to the vertical signal line SIG2. Then the selection control signal SEL2 goes low at time t9, and the readout operation ends. Taking the difference between the pixel signal and reference signal outputted to the vertical signal line SIG2 provides the signal corresponding to the amount of light incident on the photoelectric converter OE during the period V(m−1). Thereafter, the same operation as in the period V(m−1) is performed in the period V(m+1), and the same operation as in the period Vm is performed in the period V(m+2).

In Embodiment 1, the period V(m−1) exemplifies a “first readout period”, and the period Vm exemplifies a “second readout period”. In Embodiment 1, the period V(m−1) exemplifies a “first period”, and the period Vm exemplifies a “second period”.

In Embodiment 1, the first period corresponds to the entire first readout period, and the second period corresponds to the entire second readout period. However, as described in the embodiments below, the first period may correspond to part of the first readout period, and the second period may correspond to part of the second readout period.

The signal charges may be either holes or electrons. The same applies to the embodiments below.

### Timing Chart of Detailed Operation Example

In FIG. 4, the operation of a pixel 102 in a certain row is described for ease of explanation. The following describes the operation of pixels 102 in plural rows.

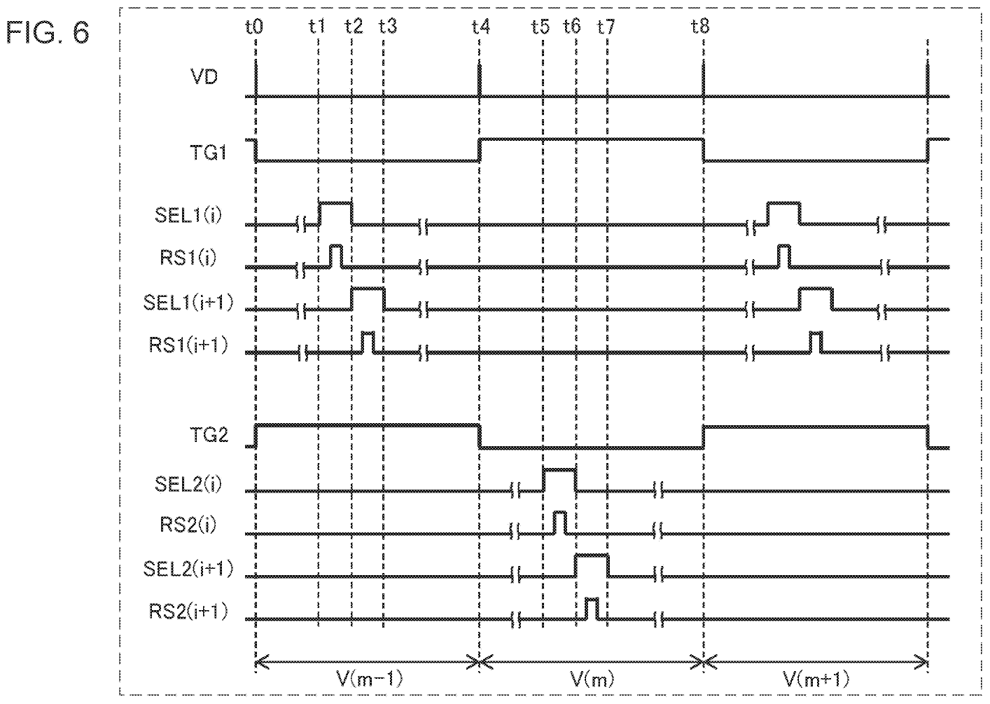

FIG. 6 is a timing chart illustrating an operation example of pixels of the imaging device according to Embodiment 1.

In FIG. 6, signals with (i) indicate signals to a pixel in i-th row among the plural rows. In a similar manner, signals with (i+1) indicate signals to a pixel in (i+1)-th row among the plural rows.

In the period V(m−1), the transfer gate signal TG1 is low for each pixel 102 in every row, and the transfer gate signal TG2 is high. In each pixel 102 in every row, therefore, signal charges generated within the photoelectric conversion layer 2 are transferred to the FD2.

In the period V(m−1), pixel signals corresponding to the amounts of signal charges accumulated in the FD1 are sequentially read row by row or in groups of plural rows. Specifically, first, the selection control signal SEL1(i) goes high to select i-th row. Then the pixel signal corresponding to the amount of signal charges accumulated in the FD1 is outputted. Thereafter, the reset control signal RS1(i) goes high to reset the FD1 to the reference potential. After the reset control signal RS1(i) goes low, the reference signal corresponding to the reference potential is outputted. The selection control signal SEL1(i) then goes low. In a similar manner, the (i+1)-th row is selected by the selection control signal SEL1(i+1), and the pixel signal and reference signal are outputted. In the period V(m−1), the pixel signal corresponding to the amount of signal charges accumulated in the FD1 is thereby read from each pixel 102 in every row.

Next, in the period Vm, the transfer gate signal TG1 is high for each pixel 102 in every row, and the transfer gate signal TG2 is low. In each pixel 102 in every row, therefore, signal charges generated within the photoelectric conversion layer 2 are transferred to the FD1.

In the period V(m), pixel signals corresponding to the amounts of signal charges accumulated in the FD2 are sequentially read row by row or in groups of plural rows. Specifically, first, the selection control signal SEL2(i) goes high to select i-th row. Then the pixel signal corresponding to the amount of signal charges accumulated in the FD2 is outputted. Thereafter, the reset control signal RS2(i) goes high to reset the FD2 to the reference potential. After the reset control signal RS2(i) goes low, the reference signal corresponding to the reference potential is outputted. The selection control signal SEL2(i) then goes low. In a similar manner, the (i+1)-th row is selected by the selection control signal SEL2(i+1), and the pixel signal and reference signal are outputted. In the period V(m), the pixel signal corresponding to the amount of signal charges accumulated in the FD2 is thereby read from each pixel 102 in every row.

According to Embodiment 1, as described above, in a certain frame period, signal charges generated in the same frame period are transferred to the FD1 while signal charges accumulated in the FD2 in the preceding frame period are read. In the subsequent frame period, signal charges generated in the same period are transferred to the FD2 while the signal charges accumulated in the FD1 in the preceding frame period are read. Accumulation and readout of signal charges are performed alternately between the FD1 and FD2 in such a manner as to implement the global shutter function and reduce or remove the dead time in exposure.

### Embodiment 2

In Embodiment 1, the first transfer gate signal TG1 and the second transfer gate signal TG2 change complementarily. Embodiment 2 is different from Embodiment 1 in including a certain period in which the first transfer gate signal TG1 and the second transfer gate signal TG2 are both low.

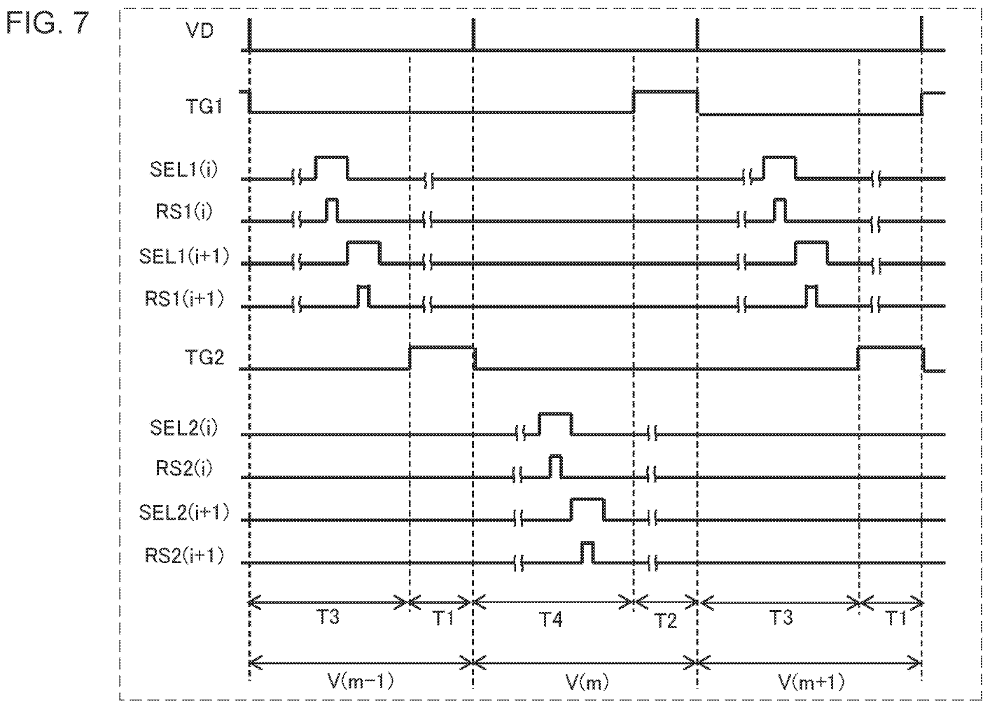

FIG. 7 is a timing chart illustrating an operation example of a pixel of an imaging device according to Embodiment 2. In the operation example of FIG. 7, the same points as those in FIG. 6 are not described, and different points are mainly described below.

In the period V(m−1), the first transfer gate signal TG1 is low. On the other hand, the second transfer gate signal TG2 is low in a period T3 and is high in a period T1. In the period T3, signal charges are held between the first and second transfer gates 11 and 21 within the semiconductor layer 3. Thereafter, the signal charges are transferred to the second electrode 20 in the period T1.

In the period V(m), the second transfer gate signal TG2 is low. On the other hand, the first transfer gate signal TG1 is low in a period T4 and is high in a subsequent period T2. In the period T4, signal charges are held between the first and second transfer gates 11 and 21 within the semiconductor layer 3. Thereafter, the signal charges are transferred to the first electrode 10 in the period T2.

In Embodiment 2, each frame period includes a period in which the first transfer gate signal TG1 and the second transfer gate signal TG2 are both low. This period is not dead time in exposure. Also in this period, signal charges generated in the photoelectric converter OE are accumulated in the semiconductor layer 3.

In Embodiment 2, the period V(m−1) exemplifies the “first readout period”, and the period Vm exemplifies the “second readout period”. In Embodiment 2, the period T1 exemplifies the “first period”, and the period T2 exemplifies the “second period”.

The potential diagram corresponding to the operation example of FIG. 7 is the same as that of FIG. 5 but is different in that (a) of FIG. 5 does not correspond to the entire period V(m−1) but corresponds only to the period T1.

According to Embodiment 2, in a certain frame period, signal charges generated in the same frame period are transferred to the FD1 while signal charges accumulated in the FD2 in the preceding frame period are read, in a manner similar to Embodiment 1. In the subsequent frame period, signal charges generated in the same frame period are transferred to the FD2 while signal charges accumulated in the FD1 in the preceding frame period are read. Accumulation and readout of signal charges are performed alternately between the FD1 and FD2 in such a manner as to implement the global shutter function and reduce or remove the dead time in exposure.

### Embodiment 3

Embodiments 1 and 2 assume that the FD1 and FD2 have the same capacitance. In Embodiment 3, the FD1 has capacitance different from that of FD2. An imaging device of Embodiment 3 thereby provides a difference in sensitivity between the detection signal acquired from the FD1 and the detection signal acquired from the FD2. Combining the detection signal acquired from the FD1 and the detection signal acquired from the FD2, for example, can expand the dynamic range.

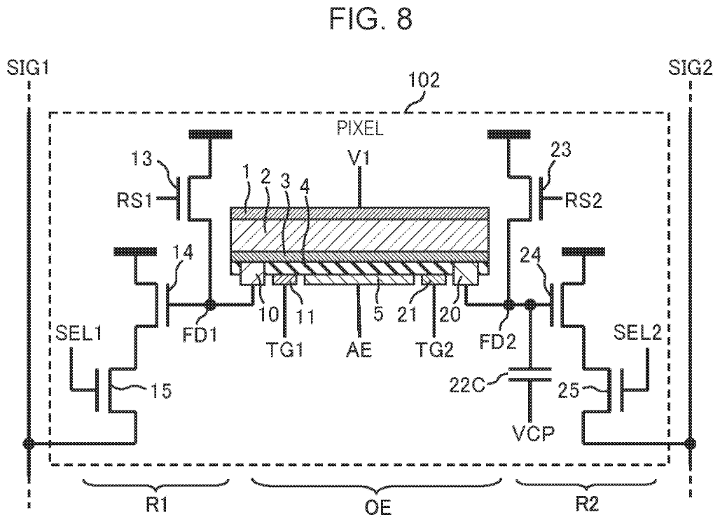

FIG. 8 is a diagram illustrating a circuit configuration example of a pixel of the imaging device according to Embodiment 3. The pixel of FIG. 8 is different from the pixel of FIG. 2A according to Embodiment 1 in further including a capacitor 22C. The other configuration and operation are the same as those of Embodiment 1 or 2 and are not described. The following mainly describes different points.

In Embodiment 3, the FD2 includes the capacitor 22C. An end of the capacitor 22C is coupled to the second electrode 20, the source of the second reset transistor 23, and the gate of the second amplification transistor 24. To the other end of the capacitor 22C, a predetermined voltage VCP is applied. The predetermined voltage VCP is to control the amount of charges that can be accumulated in the capacitor 22C.

In Embodiment 3, because of the additional capacitor 22C, the capacitance of the FD2 is greater than that of the FD1. The sensitivity of the detection signal outputted from the first amplification transistor 14 is therefore higher than that of the detection signal outputted from the second amplification transistor 24. Combining these detection signals, for example, can expand the dynamic range.

In Embodiment 3, the capacitor 22C is added. However, the present disclosure is not limited to this configuration. For example, the first and second diffusion layers 12 and 22 in FIG. 3 may be differently configured so that the capacitance of the second diffusion layer 22 be greater than that of the first diffusion layer 12.

Alternatively, the exposure period corresponding to the detection signal acquired from the FD1 may be different in length from the exposure time corresponding to the detection signal acquired from the FD2. Specifically, the exposure period in which signal charges to be transferred to the FD1 are generated may be different in length from the exposure period in which signal charges to be transferred to the FD2 are generated. In FIG. 7, for example, the length of the periods V(m), V(m+2), and the like may be greater than that of the periods V(m−1), V(m+1), and the like. Alternatively, in FIG. 7, for example, the period T1 may be shifted earlier in the periods V(m−1), V(m+1), and the like so that the period from the end of the period T1 to the end of the next period T2 be longer than the period from the end of the period T2 to the end of the next period T1. Even in such a configuration, combining the detection signals acquired from the FD1 and FD2 can expand the dynamic range.

### Embodiment 4

Embodiments 1 to 3 describe the operation examples of alternately changing the transfer gate signals TG1 and TG2 on a frame-by-frame basis. Embodiment 4 describes an operation example of changing the transfer gate signals TG1 and TG2 in each frame. In Embodiment 4, excess signal charges that cannot be transferred to the FD1 and remain above the charge accumulation electrode 5 are transferred to the FD2.

The circuit configuration of a pixel 102 of the imaging device according to Embodiment 4 is the same as that of FIG. 8 according to Embodiment 3.

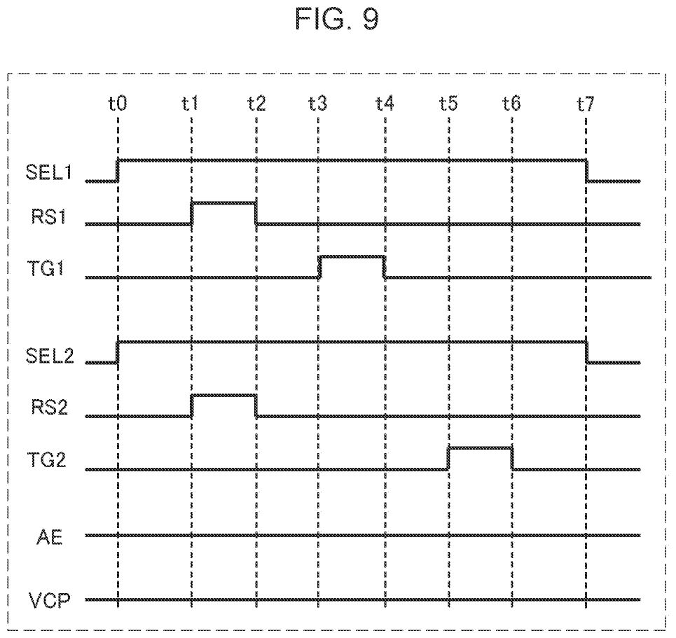

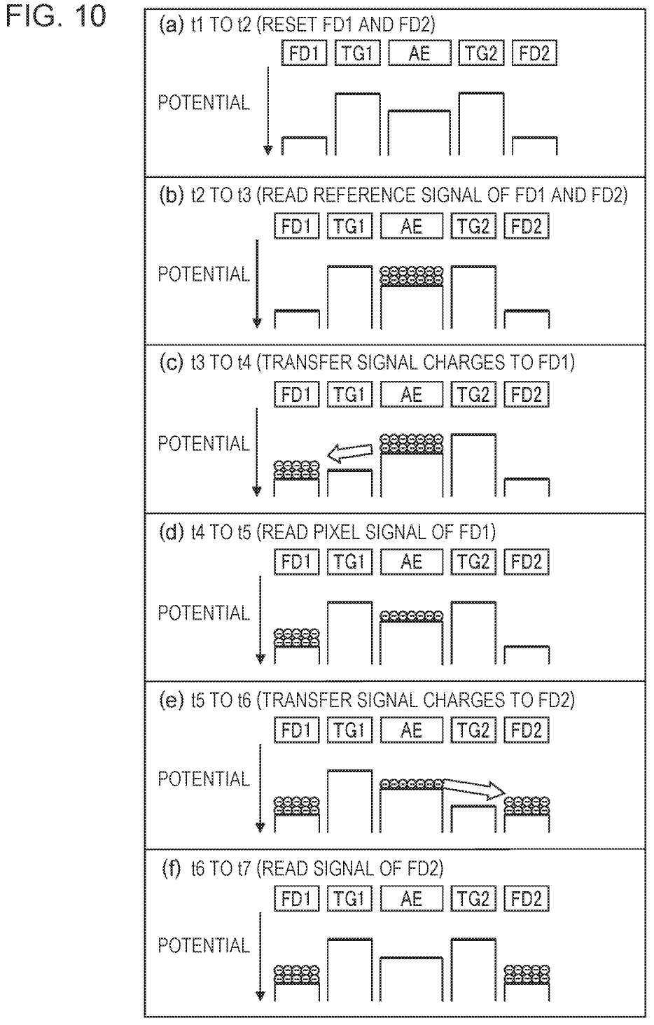

FIG. 9 is a timing chart illustrating an operation example of a pixel of the imaging device of Embodiment 4. FIG. 10 illustrates a potential profile of a pixel 102 in each period in FIG. 9.

In the period from time t0 to time t7, the selection control signals SEL1 and SEL2 are high. In this period, signals from the pixel 102 are outputted to the vertical signal lines SIG1 and SIG2.

In the period from time t1 to time t2, the reset control signals RS1 and RS2 are high. The potentials of the FD1 and FD2 are reset to reference potentials VRST1 and VRST2, respectively.

In the period from time t2 to time t3, a signal VR1 corresponding to the reference potential VRST1 is outputted to the vertical signal line SIG1, and a signal VR2 corresponding to the reference potential VRST2 is outputted to the vertical signal line SIG2.

In the period from time t3 to time t4, the transfer gate signal TG1 is high, and signal charges accumulated above the charge accumulation electrode 5 are transferred to the FD1. In this process, when the amount of the accumulated signal charges is greater than a predetermined amount, the FD1 is saturated, and some signal charges are not transferred to the FD1 and remain above the charge accumulation electrode 5.

In the period from t4 to time t5, a signal VS1 corresponding to the amount of signal charges transferred to the FD1 is outputted to the vertical signal line SIG1. The signal processing circuit 104 on the output side acquires a signal corresponding to the amount of signal charges transferred to the FD1 by correlated double sampling for the signals VS1 and the signal VR1.

In the period from time t5 to time t6, the transfer gate signal TG2 is high. The signal charges that are not transferred to the FD1 and remain above the charge accumulation electrode 5 are thereby transferred to the FD2. Since the FD2 includes the capacitor 22C, the FD2 has a greater capacitance than the FD1. The FD2 is therefore able to accumulate more signal charges than the FD1.

In the period from t6 to time t7, a signal VS2 corresponding to the amount of signal charges transferred to the FD2 is outputted to the vertical signal line SIG2. The signal processing circuit 104 on the output side acquires a signal corresponding to the amount of signal charges that are not transferred to the FD1 and remain above the charge accumulation electrode 5, that is, the amount of signal charges transferred to the FD2, by correlated double sampling for the signal VS2 and the signal VR2.

In Embodiment 4, the capacitance of the FD1 is smaller than that of the FD2. The signal charges transferred to the FD1 can thereby produce a high-sensitivity detection signal. The signal charges that are not transferred to the FD1 to remain in the semiconductor layer 3 above the charge accumulation electrode 5 and are then transferred to the FD2 can produce a low-sensitivity detection signal. Combining these detection signals, for example, can expand the dynamic range. These signal charges are acquired for substantially the same exposure period, and there is little difference in exposure period between the image acquired from the high-sensitivity detection signal and the image acquired from the low-sensitivity detection signal. Furthermore, since these signal charges are acquired by photoelectric conversion with the same photoelectric converter OE, the optical center of the image acquired from the high-sensitivity detection signal is the same as that of the image acquired from the low-sensitivity detection signal. According to Embodiment 4, as described above, the dynamic range can be expanded with little gap in exposure time and optical center.

### Embodiment 5

Embodiments 1 to 3 describe the operation examples of alternately changing the transfer gate signals TG1 and TG2. Embodiment 5 describes an operation example in which the transfer gate signal TG1 is always high while the transfer gate signal TG2 is always low or middle.

The circuit configuration of a pixel of an imaging device according to Embodiment 5 is the same as that of FIG. 8 according to Embodiment 3.

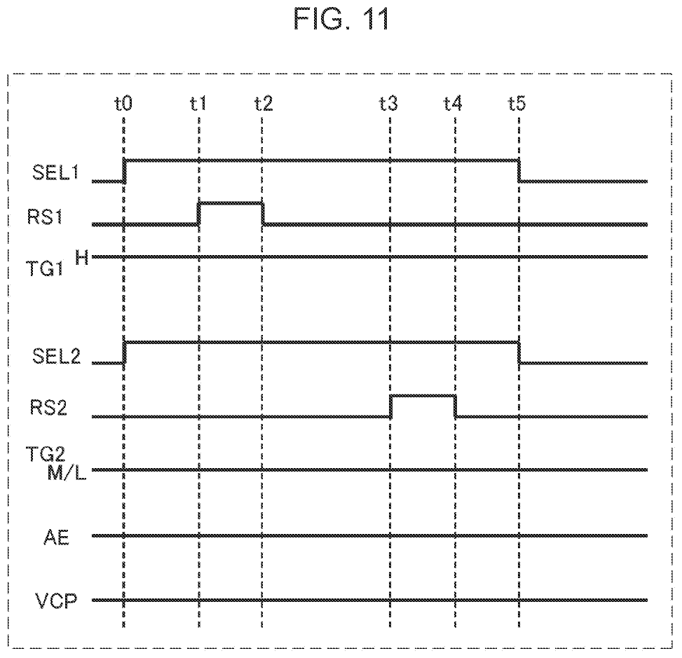

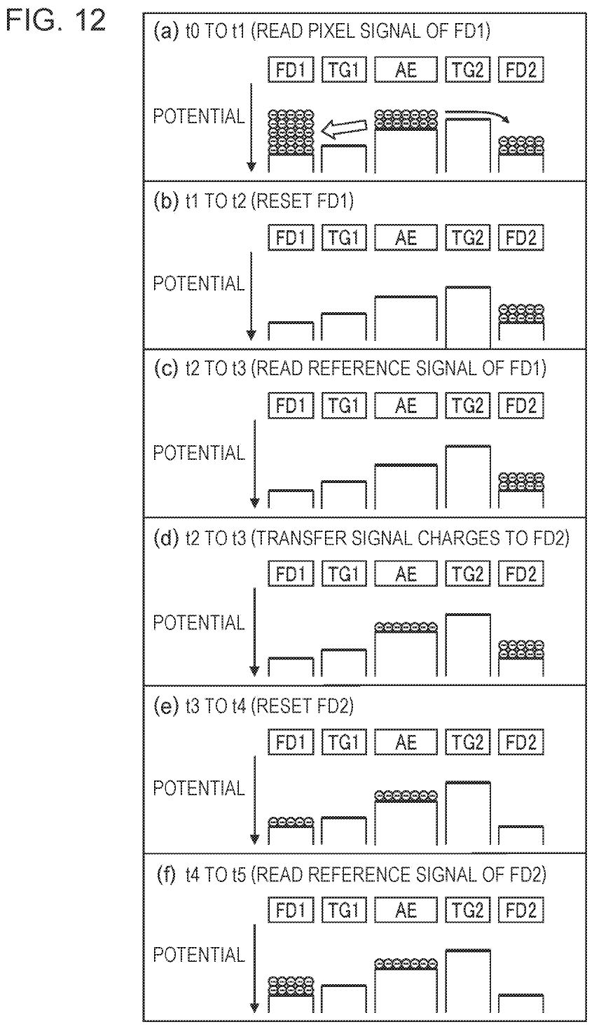

FIG. 11 is a timing chart illustrating an operation example of a pixel of the imaging device according to Embodiment 5. In FIG. 11, “H” indicates the high level; “M” indicates the middle level; and “L” indicates the low level. In FIG. 11, the transfer gate signal TG1 is always high, and the transfer gate signal TG2 is always middle or low. FIG. 12 is a diagram illustrating a potential profile of a pixel 102 in each period in FIG. 11.

In Embodiment 5, charges generated above the charge accumulation electrode 5 are first accumulated in the FD1. When light is intense and charges accumulated in the FD1 exceed the potential barrier above the second transfer gate 21, excess charges that cannot be accumulated in the FD1 are accumulated in the FD2.

In FIG. 11, at time t0, the selection control signals SEL1 and SEL2 change from low to high. This starts the period of outputting signals from the pixel 102 to the vertical signal lines SIG1 and SIG2. Since the transfer gate signal TG1 is always high, the signal charges generated by photoelectric conversion are already accumulated in the FD1 at time t0.

In the period from time t0 to time t1, the signal VS1 corresponding to the amount of signal charges accumulated in the FD1 is outputted to the vertical signal line SIG1.

In the period from time t1 to time t2, the reset control signal RS1 is high. The potential of the FD1 is thereby reset to the reference potential VRST1.

In the period from time t2 to time t3, the signal VR1 corresponding to the reference potential VRST1 is outputted to the vertical signal line SIG1. The signal processing circuit 104 on the output side acquires by correlated double sampling for the signals VS1 and VR1, a signal corresponding to the amount of signal charges accumulated in the FD1.

When signal charges greater than or equal to the amount of signal charges that can be accumulated in the FD1 are generated in the exposure period, excess charges are transferred to the FD2 over the potential barrier by the second transfer gate 21. Since the FD2 additionally includes the capacitor 22C, the FD2 has a greater capacitance than the FD1. The FD2 is able to accumulate more signal charges than the FD1.

In the period from time t2 to time t3, the signal VS2 corresponding to the amount of signal charges accumulated in the FD2 is outputted to the vertical signal line SIG2.

In the period from time t3 to time t4, the reset control signal RS2 is high. The potential of the FD2 is reset to the reference potential VRST2.

In the period from time t4 to time t5, the signal VR2 corresponding to the reference potential VRST2 is outputted to the vertical signal line SIG2. The signal processing circuit 104 on the output side acquires by correlated double sampling for the signals VS2 and VR2, a signal corresponding to the amount of signal charges transferred to the FD2.

In the imaging device according to Embodiment 5, the signal charges accumulated in the FD1 produce a high-sensitivity detection signal. The signal charges transferred to the FD2 over the potential barrier by the second transfer gate 21 produce a low-sensitivity detection signal. Combining these detection signals, for example, can expand the dynamic range. These signal charges are acquired in substantially the same exposure period, and there is little difference in exposure period between the image acquired from the high-sensitivity detection signal and the image acquired from the low-sensitivity detection signal. Furthermore, since these signal charges are acquired by photoelectric conversion with the same photoelectric converter OE, the optical center of the image acquired from the high-sensitivity detection signal is the same as that of the image acquired from the low-sensitivity detection signal. According to Embodiment 5, as described above, the dynamic range can be expanded with little gap in exposure time and optical center.

The level of the transfer gate signal TG2 may be determined depending on the required sensitivity between the low and the high level. The level of the transfer gate signal TG2 may be fixed or may be varied depending on the imaging environment.

### Embodiment 6

Embodiments 1 to 5 describe the configuration examples including the readout circuits R1 and R2. Embodiment 6 describes a configuration example including one readout circuit.

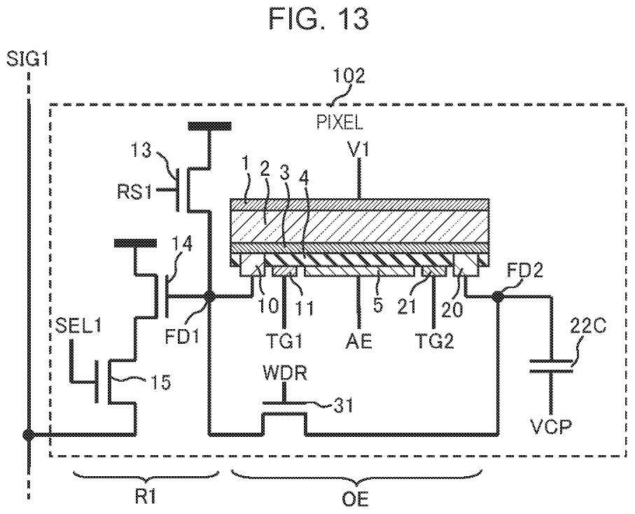

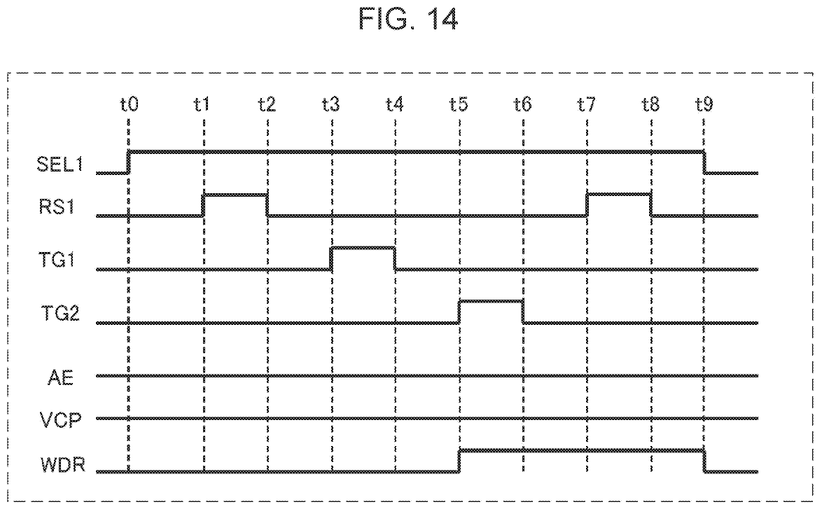

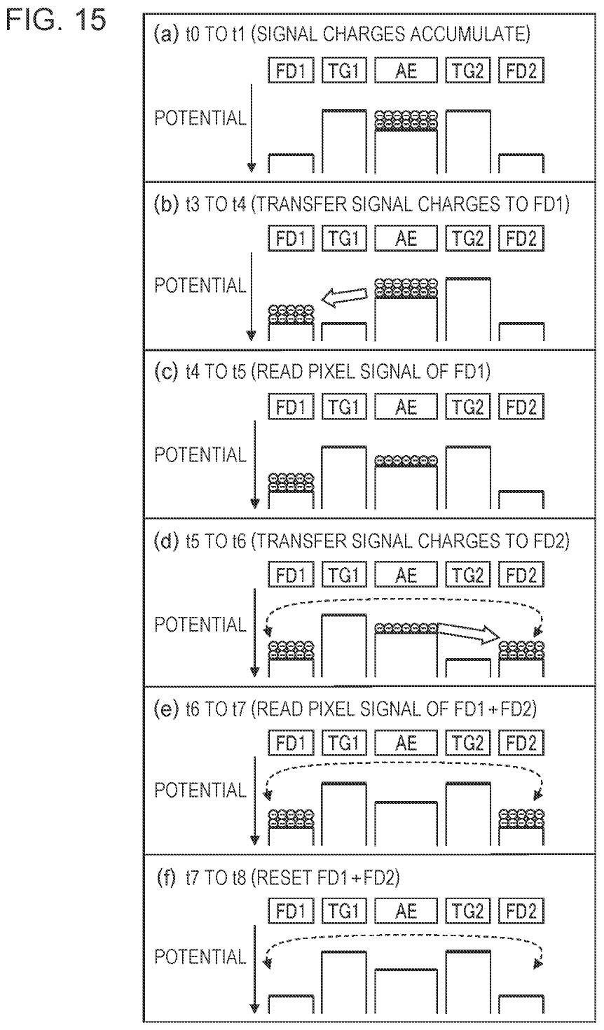

FIG. 13 is a diagram illustrating a circuit configuration example of a pixel of an imaging device according to Embodiment 6. FIG. 14 is a timing chart illustrating an operation example of a pixel of the imaging device according to Embodiment 6. FIG. 15 is a diagram illustrating a potential profile of a pixel 102 in each period in FIG. 14.

The circuit configuration of a pixel of FIG. 13 is different from that of FIG. 8 in not including the readout circuit R2 and additionally including a coupling switch 31. The following mainly describes different points. The coupling switch 31 switches whether to couple the FD2 to the FD1. This means that the coupling switch 31 changes the capacitance of the FD1. The coupling switch 31 is off when a switch control signal WDR is low and is on when the switch control signal WDR is high, for example.

In FIG. 14, at time t0, the selection control signal SEL1 changes from low to high. This starts the period of outputting a signal from the pixel 102 to the vertical signal line SIG1.

In the period from time t1 to time t2, the reset control signal RS1 is high. The potential of the FD1 is thereby reset to the reference potential VRST1.

In the period from time t2 to time t3, the signal VR1 corresponding to the reference potential VRST1 is outputted to the vertical signal line SIG1.

In the period from time t3 to time t4, the transfer gate signal TG1 is high. The signal charges accumulated above the charge accumulation electrode 5 are transferred to the FD1.

In the period from time t4 to time t5, the signal VS1 corresponding to the amount of signal charges transferred to the FD1 is outputted to the vertical signal line SIG1. The signal processing circuit 104 on the output side acquires by correlated double sampling for the signals VS1 and VR1, a signal corresponding to the amount of signal charges transferred to the FD1.

In the period from time t5 to time t6, the transfer gate signal TG2 is high. When the amount of signal charges accumulated above the charge accumulation electrode 5 is greater than or equal to the amount of signal charges that can be transferred to the FD1, the excess signal charges are thereby transferred to the FD2. Since the FD2 additionally includes the capacitor 22C, the FD2 has a greater capacitance than the FD1. It is therefore possible to transfer and accumulate more signal charges in the FD2 than in the FD1.

In the period from time t5 to time t9, the switch control signal WDR is high. The FD1 and the FD2 are thereby short-circuited to combine the signal charges transferred to the FD1 and the signal charges transferred to the FD2.

In the period from time t6 to time t7, the signal VS2 corresponding to the amount of signal charges accumulated in the FD1 and FD2 is outputted to the vertical signal line SIG1.

In the period from time t7 to time t8, the reset control signal RS1 is high again. The potentials of the FD1 and the FD2 are therefore reset to the reference potential VRST1.

In the period from time t8 to time t9, the signal VR2 corresponding to the reference potential VRST1 is outputted to the vertical signal line SIG1. The signal processing circuit 104 on the output side acquires by correlated double sampling for the signals VS2 and VR2, a signal corresponding to the total amount of the signal charges transferred to the FD1 and the signal charges transferred to the FD2.

According to Embodiment 6, the signal charges transferred to the FD1 produce a high-sensitivity detection signal. The signal charges as the sum of the signal charges transferred to the FD1 and the signal charges transferred to the FD2, produce a low-sensitivity detection signal. Combining these detection signals, for example, can expand the dynamic range. These signal charges are acquired in substantially the same exposure period, and there is little difference in exposure period between the image acquired from the high-sensitivity detection signal and the image acquired from the low-sensitivity detection signal. Furthermore, since these signal charges are acquired by photoelectric conversion with the same photoelectric converter OE, the optical center of the image acquired from the high-sensitivity detection signal is the same as that of the image acquired from the low-sensitivity detection signal. According to Embodiment 6, as described above, the dynamic range can be expanded with little gap in exposure time and optical center.

Generally, signal charges involve noise of √N, called optical shot noise, corresponding to the square root of the number of the charges. In Embodiment 6, the signal charges transferred to the FD2 are combined with the signal charges transferred to the FD1 to be read. This can improve the S/N(=N/√N) by the optical shot noise.

### Embodiment 7

Embodiment 7 is different from Embodiment 6 in that the second transfer gate 21 is always middle or low. The circuit configuration example of a pixel of an imaging device according to Embodiment 7 is the same as that in FIG. 13 according to Embodiment 6.

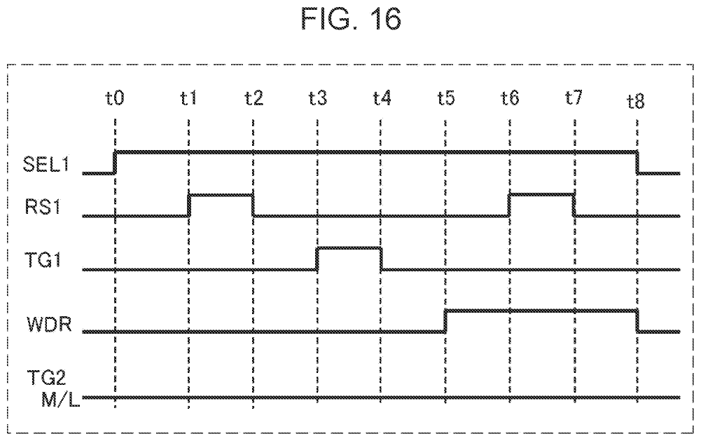

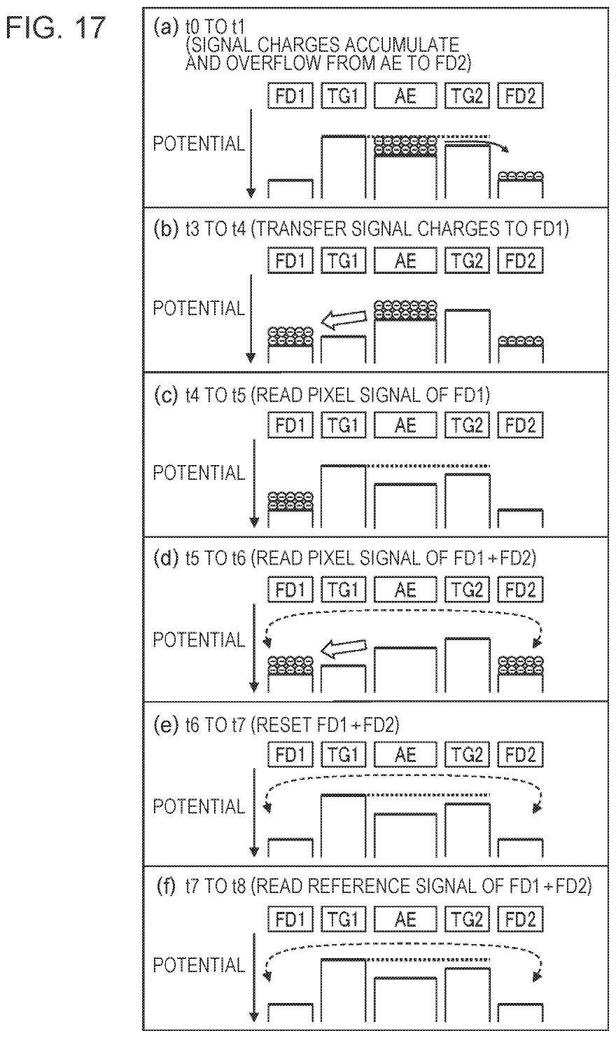

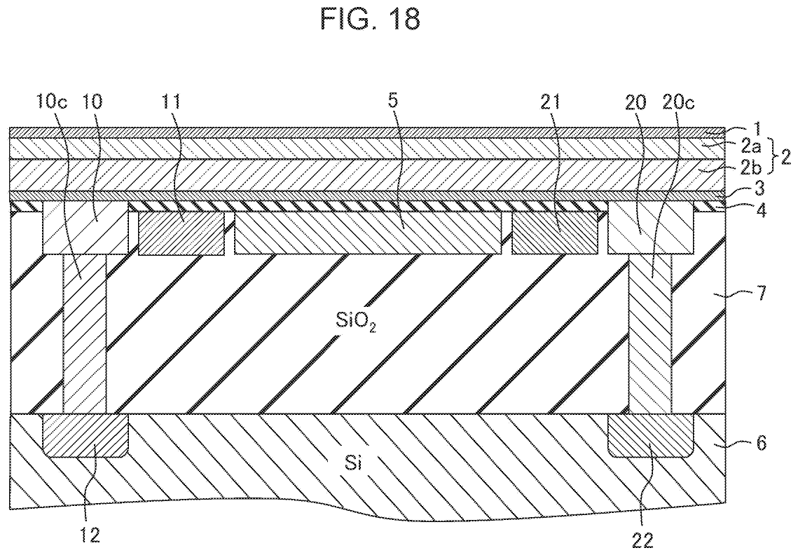

FIG. 16 is a timing chart illustrating an operation example of a pixel of the imaging device according to Embodiment 7. FIG. 17 is a diagram illustrating a potential profile of a pixel 102 in each period in FIG. 16.

In Embodiment 7, signal charges generated in the photoelectric conversion layer 2 are accumulated above the charge accumulation electrode 5 due to potential barriers formed by the first transfer gate 11 and the second transfer gate 21. The voltage values of the transfer gate signal TG1 and transfer gate signal TG2 are set so that the potential barrier by the first transfer gate 11 be higher than the potential barrier by the second transfer gate 21. The potential barrier above the first transfer gate 11 and the potential barrier above the second transfer gate 21 can be set depending on the concentration of impurities used for doping the regions in the semiconductor layer 3 above the first transfer gate 11 and second transfer gate 21. In Embodiment 7, when the amount of signal charges accumulated above the charge accumulation electrode 5 is greater than or equal to a predetermined amount, the excess signal charges beyond the predetermined amount are transferred to the FD2 over the potential barrier formed by the second transfer gate 21.

In FIG. 16, the selection control signal SEL1 changes from low to high at time t0. This starts the period of outputting a signal from the pixel to the vertical signal line SIG1.

In the period from time t1 to time t2, the reset control signal RS1 is high. The potential of the FD1 is thereby reset to the reference potential VRST1.

In the period from time t2 to time t3, the signal VR1 corresponding to the reference potential VRST1 is outputted to the vertical signal line SIG1.

In the period from time t3 to time t4, the transfer gate signal TG1 is high. The signal charges accumulated above the charge accumulation electrode 5 are thereby transferred to the FD1. Herein, in Embodiment 7, the potential barrier by the second transfer gate 21 is lower than the potential barrier by the first transfer gate 11. The signal charges that are generated in the exposure period and can move over the potential barrier by the second transfer gate 21 are therefore already transferred to the FD2.

In the period from time t4 to time t5, the signal VS1 corresponding to the amount of signal charges transferred to the FD1 is outputted to the vertical signal line SIG1. The signal processing circuit 104 on the output side acquires by correlated double sampling for the signals VS1 and VR1, a signal corresponding to the amount of signal charges transferred to the FD1.

In the period from time t5 to time t8, the switch control signal WDR is high. The FD1 and the FD2 are thereby short-circuited to combine the signal charges transferred to the FD1 and the signal charges transferred to the FD2.

In the period from time t5 to time t6, the signal VS2 corresponding to the total amount of the combined signal charges is outputted to the vertical signal line SIG1.

In the period from time t6 to time t7, the reset control signal RS1 is high again. The potentials of the FD1 and the FD2 are thereby reset to the reference potential VRST1.

In the period from time t7 to time t8, the signal VR2 corresponding to the reference potential VRST1 is outputted to the vertical signal line SIG1. The signal processing circuit 104 on the output side acquires by correlated double sampling for the signals VS2 and VR2, a signal corresponding to the total amount of the signal charges transferred to the FD1 and the signal charges transferred to the FD2.

According to Embodiment 7, the signal charges transferred to the FD1 produce a high-sensitivity detection signal. The signal charges, as the sum of the signal charges transferred to the FD1 and the signal charges transferred to the FD2, produce a low-sensitivity detection signal. Combining these detection signals, for example, can expand the dynamic range. These signal charges are acquired in substantially the same exposure period, and there is little difference in exposure period between the image acquired from the high-sensitivity detection signal and the image acquired from the low-sensitivity detection signal. Furthermore, since these signal charges are acquired by photoelectric conversion with the same photoelectric converter OE, the optical center of the image acquired from the high-sensitivity detection signal is the same as that of the image acquired from the low-sensitivity detection signal. According to Embodiment 7, as described above, the dynamic range can be expanded with little gap in exposure time and optical center. Still furthermore, the signal VS2 of the high saturation pixel includes the signal VS1 of the high-sensitivity pixel, inhibiting S/N by optical shot noise from degrading. In Embodiment 7, excess signal charges, which cannot be read in the conventional examples, are transferred to the FD2 to be read, thus implementing a wide dynamic range.

### Embodiment 8

Embodiment 8 describes an operation example of varying the spectral sensitivity characteristic of the photoelectric conversion layer 2.

FIG. 18 is a diagram illustrating a sectional structure of a pixel 102. The sectional structure of FIG. 18 is different from that of FIG. 3 in that the photoelectric conversion layer 2 has a stacking structure composed of a first photoelectric conversion layer 2a and a second photoelectric conversion layer 2b. The following mainly describes different points.

The first photoelectric conversion layer 2a and the second photoelectric conversion layer 2b are different in spectral sensitivity characteristic. For example, the first photoelectric conversion layer 2a has a sensitivity in the visible wavelength range. The second photoelectric conversion layer 2b has a sensitivity in the infrared wavelength range.

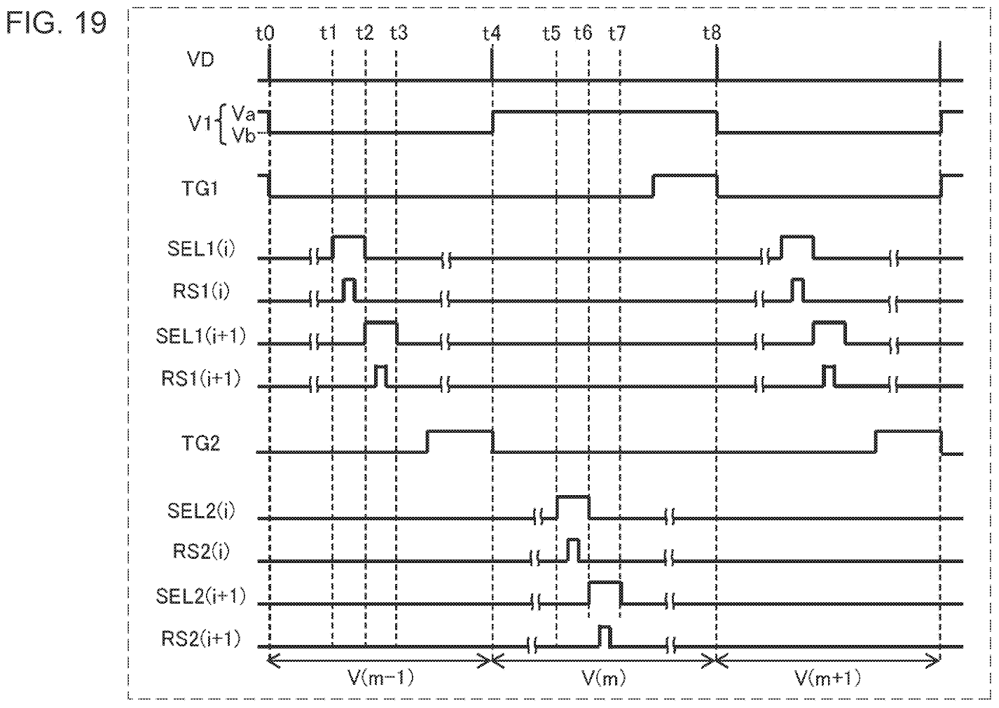

FIG. 19 is a timing chart illustrating drive of a pixel of an imaging device according to Embodiment 8. FIG. 19 is different from FIG. 7 in that the voltage applied to the counter electrode 1 changes. In FIG. 19, V1, the second line from the top, indicates changes in the voltage applied to the counter electrode 1. In the frame period V(m−1), voltage Vb is applied to the counter electrode 1. In the frame period V(m), voltage Va, which is different from the voltage Vb, is applied to the counter electrode 1. Herein, the voltage Va is higher than the voltage Vb. The voltage Va and the voltage Vb are alternately applied to the counter electrode 1 on a frame-by-frame basis after the frame period V(m).

In the frame period V(m−1), since a comparatively large bias voltage is applied to the photoelectric conversion layer 2, both the first photoelectric conversion layer 2a and the second photoelectric conversion layer 2b perform photoelectric conversion. The pixel 102 has sensitivities both in the visible wavelength range and in the infrared wavelength range. In the frame period V(m), since a comparatively small bias voltage is applied to the photoelectric conversion layer 2, the first photoelectric conversion layer 2a performs photoelectric conversion, but the second photoelectric conversion layer 2b does not perform photoelectric conversion. The pixel 102 has a sensitivity in the visible wavelength range but does not have a sensitivity in the infrared wavelength range.

In such a manner, the voltage V1 applied to the counter electrode 1 changes frame by frame. The imaging device according to Embodiment 8 provides an image signal based on visible light and infrared light in a certain frame period and provides an image signal based on visible light in another frame period. The aforementioned technique to change the spectral sensitivity characteristic is disclosed in International Publication No. WO2018/025544 in detail, which is incorporated herein by reference.

In the example illustrated in FIG. 19, the voltage V1 applied to the counter electrode 1 changes. However, the voltage V1 of the counter electrode 1 may be constant while the voltage of the charge accumulation electrode 5 changes. In this case, voltages of the first transfer gate 11, second transfer gate 21, first electrode 10, and second electrode 20 may be changed with the voltage of the charge accumulation electrode 5 so that the change in the voltage of the charge accumulation electrode 5 not affect transfer of signal charges. The technique to change the potentials of the first electrode 10 and the second electrode 20 is described in detail in Japanese Unexamined Patent Application Publication No. 2019-054499, which is incorporated herein by reference. According to such a configuration, the imaging device also provides an image signal based on visible light and infrared light in a certain frame period and provides an image signal based on visible light in another frame period.

The photoelectric conversion layer 2 may be composed of a single layer. In this case, the spectral sensitivity characteristic cannot be varied, but the quantum efficiency of the photoelectric conversion layer 2 may be varied by changing the bias voltage. This allows the imaging device to provide a high-sensitivity detection signal in a certain frame period and provide a low-sensitivity detection signal in another frame period. Combining these detection signals can expand the dynamic range.

### Embodiment 9

Embodiment 9 describes a configuration example to provide negative feedback of the potential of the first electrode 10, that is, the potential of the first charge accumulator FD1 at the reset operation.

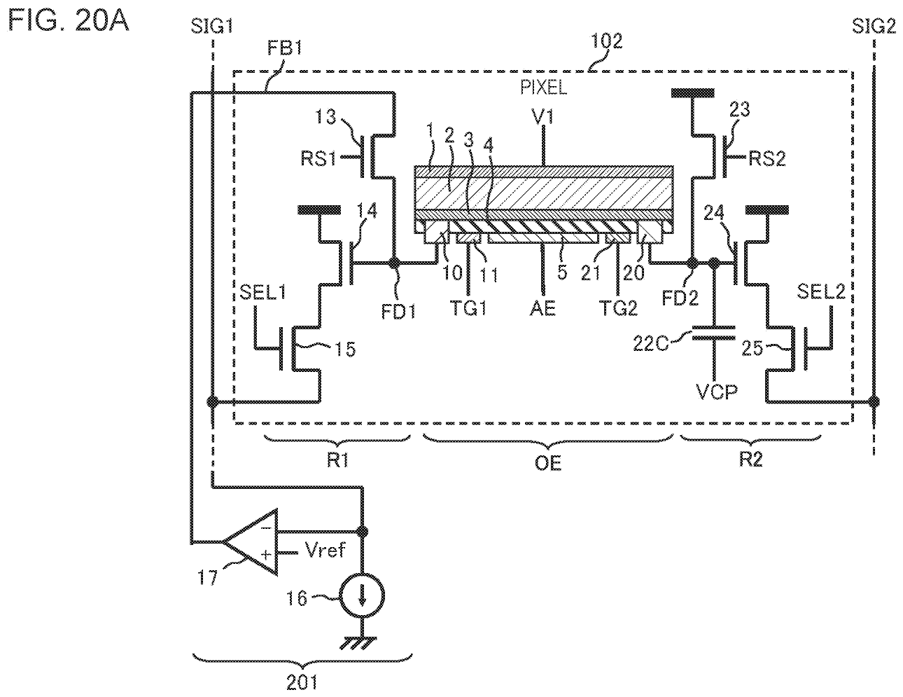

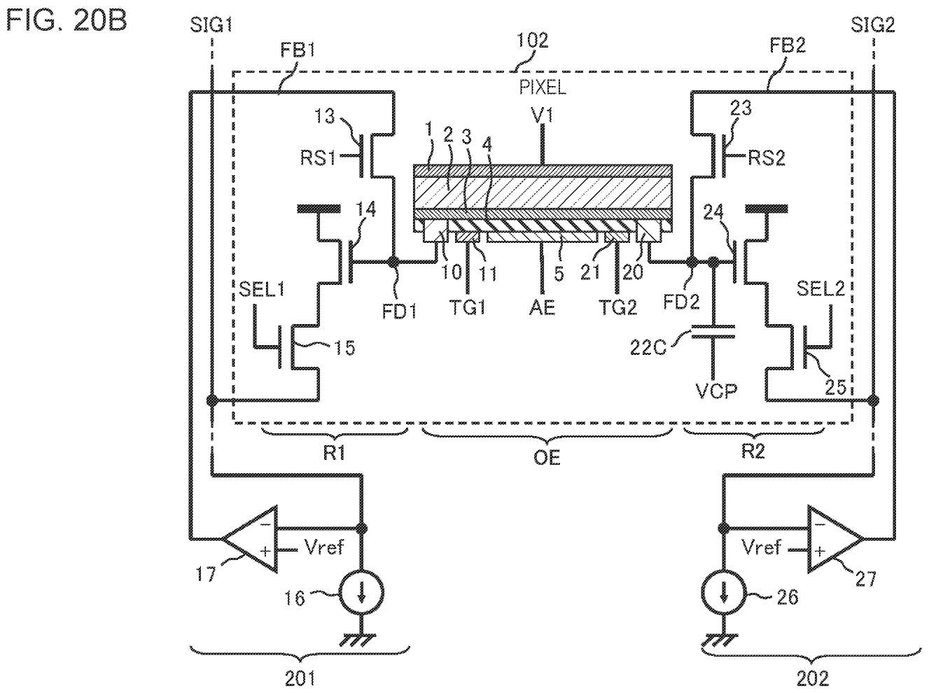

FIG. 20A is a diagram illustrating a circuit configuration example of a pixel of an imaging device according to Embodiment 9. The circuit configuration of FIG. 20A is different from that of FIG. 8 in that the readout circuit R1 includes a feedback circuit 201. The following mainly describes different points.

The feedback circuit 201 includes a differential amplifier 17 provided for each column. The feedback circuit 201 provides negative feedback of the potential of the FD1 to the FD1 through the first amplification transistor 14, first selection transistor 15, differential amplifier 17, and first reset transistor 13 at the reset operation. This can reduce kTC noise generated when the first reset transistor 13 is turned off.

The aforementioned technique to reduce kTC noise is disclosed in, for example, Japanese Unexamined Patent Application Publication No. 2017-046333, which is incorporated herein by reference.

As illustrated in FIG. 20B, the readout circuit R2 may include a feedback circuit 202, which is similar to the feedback circuit 201.

In FIG. 20A, the second transfer gate 21, second electrode 20, and readout circuit R2 may be omitted. In this case, the signal charges accumulated above the charge accumulation electrode 5 are transferred only to the first electrode 10. In this case, in a certain frame period, signal charges accumulated above the charge accumulation electrode 5 may be transferred to the FD1 simultaneously in every pixel. Then the signals corresponding to the amounts of signal charges transferred to the FD1 may be sequentially outputted to the vertical signal line SIG1. Concurrently with outputting the signals, signal charges of the next frame may be accumulated above the charge accumulation electrode 5. Such an operation also implements the global shutter function and reduces the dead time in exposure.

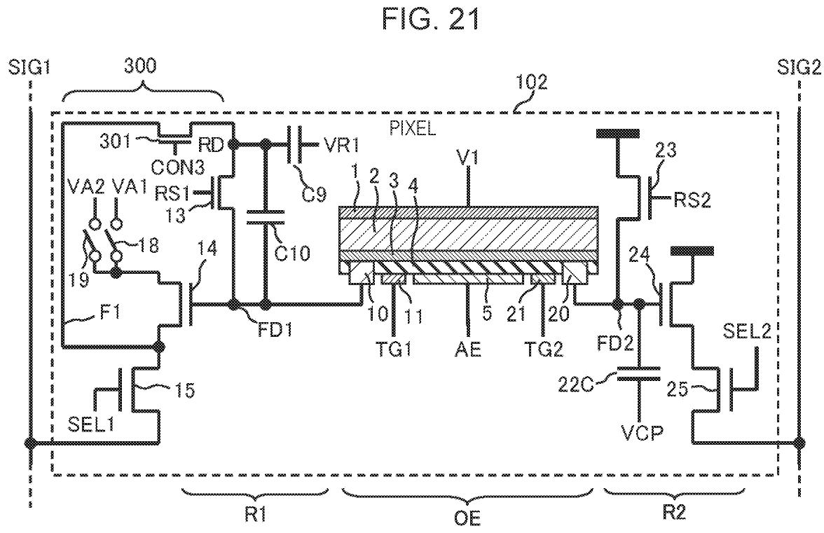

FIG. 21 is a diagram illustrating a modification of the circuit configuration of a pixel of the imaging device according to Embodiment 9. The circuit configuration of FIG. 21 is different from that of FIG. 20A in that the readout circuit R1 includes a feedback circuit 300 instead of the feedback circuit 201. The following mainly describes different points.

The feedback circuit 300 includes a transistor 301, a capacitor C9, and a capacitor C10. One of the source and drain of the first amplification transistor 14 is selectively supplied with one of voltage VA1 and voltage VA2. The other one of the source and drain of the first amplification transistor 14 is coupled to the vertical signal line SIG1 through the first selection transistor 15. The feedback circuit 300 provides negative feedback of the potential of the FD1 to the FD1 through the first amplification transistor 14, first selection transistor 15, and transistor 301 at the reset operation.

At the reset operation, a switch 18 is on while a switch 19 is off. At the readout operation to read signals from the pixel 102, the switch 18 is off while the switch 19 is on. The first amplification transistor 14 thereby operates as a common source amplifier at the reset operation. At the readout operation, the first amplification transistor 14 operates as a source follower amplifier and outputs a signal to the vertical signal line SIG1.

The aforementioned technique to reduce kTC noise is disclosed in Japanese Unexamined Patent Application Publication No. 2016-127593, which is incorporated herein by reference.

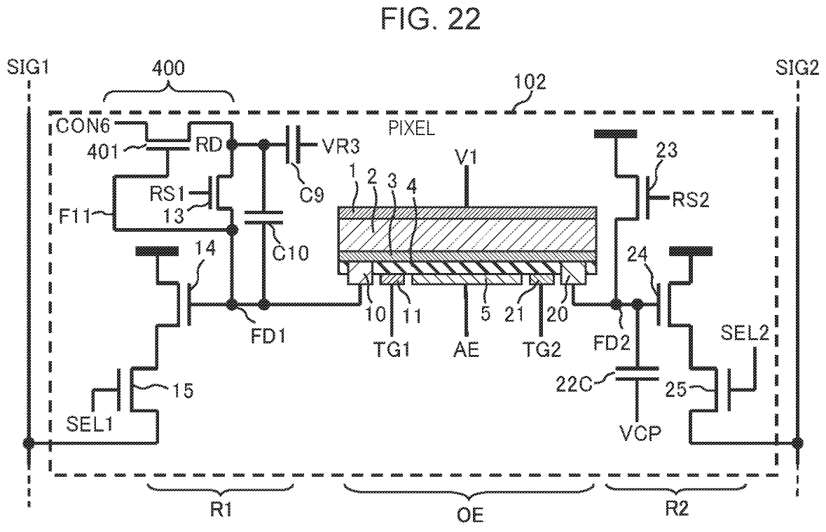

FIG. 22 is a diagram illustrating another modification of the circuit configuration of a pixel of an imaging device according to Embodiment 9. The circuit configuration of FIG. 22 is different from that of FIG. 21 in that the readout circuit R1 includes a feedback circuit 400 instead of the feedback circuit 300. The following mainly describes different points.

The feedback circuit 400 includes a transistor 401, the capacitor C9, and the capacitor C10. The feedback circuit 400 provides negative feedback of the potential of the FD1 to the FD1 through the transistor 401 and the first reset transistor 13 at the reset operation.

The aforementioned technique to reduce kTC noise is disclosed in Japanese Unexamined Patent Application Publication No. 2016-127593, which is incorporated herein by reference.

According to the imaging device of the another modification, it is possible to reduce kTC noise generated when the first reset transistor 13 is turned off at the reset operation.

The processors included in each of the imaging devices according to the aforementioned embodiments are typically implemented as LSIs, which are integrated circuits. These may be individually implemented in a chip or may be implemented in chips including some or all of the LSIs.

The integrated circuits are not limited to LSIs and may be implemented by a dedicated circuit or a general-purpose processor. The processors may be implemented using a field programmable gate array (FPGA), which is programmable after manufacturing of the LSIs, or a configurable processor that enables reconfiguration of connections and settings of circuit cells within the LSIs.

In the aforementioned embodiments, some of the constituent components may be implemented by execution of a software program suitable for the constituent component. The constituent components may be implemented by a program execution section, such as a CPU or a processor, reading and executing a software program recorded in a recording medium, such as a hard disk or a semiconductor memory.

Each of the aforementioned embodiments can be subjected to various changes, substitutions, additions, omissions, and the like within the scope of claims or within an equivalent scope thereto.

The imaging device and imaging system according to the present disclosure are applicable to various camera systems or sensor systems of digital still cameras, medical cameras, monitoring cameras, in-vehicle cameras, digital single-lens reflex cameras, digital mirrorless single-lens reflex cameras, and other imaging apparatuses.

What is claimed is:

1. An imaging device comprising:
pixels, each of the pixels including:
a photoelectric conversion layer that converts light into signal charges;
a counter electrode that applies bias voltage to the photoelectric conversion layer;
a first electrode and a second electrode that are spaced from each other and collect the signal charges generated in the photoelectric conversion layer;
a first transfer gate that controls transfer of the signal charges to the first electrode;
a second transfer gate that controls transfer of the signal charges to the second electrode;
a first amplification transistor that includes a first gate electrically coupled to the first electrode; and
a second amplification transistor that includes a second gate electrically coupled to the second electrode, wherein
the first transfer gate suppresses the transfer of the signal charges to the first electrode in a first readout period in which the first amplification transistor outputs a signal corresponding to a potential of the first gate,
the second transfer gate suppresses the transfer of the signal charges to the second electrode in a second readout period in which the second amplification transistor outputs a signal corresponding to a potential of the second gate,
the first readout period includes a first period in which the second transfer gate allows the transfer of the signal charges to the second electrode, and
the second readout period includes a second period in which the first transfer gate allows the transfer of the signal charges to the first electrode.

2. The imaging device according to claim 1, wherein
a length of the first period is the same as a length of the first readout period, and
a length of the second period is the same as a length of the second readout period.

3. The imaging device according to claim 1, wherein the first readout period and the second readout period are continuously alternated.

4. The imaging device according to claim 1, wherein
the first readout period includes a third period immediately before the first period,
in the third period, the second transfer gate suppresses the transfer of the signal charges to the second electrode,
the second readout period includes a fourth period immediately before the second period, and
in the fourth period, the first transfer gate suppresses the transfer of the signal charges to the first electrode.

5. The imaging device according to claim 1, wherein
each of the plurality of pixels further includes
a first charge accumulator that is electrically coupled to the first electrode and accumulates the signal charges collected by the first electrode, and
a second charge accumulator that is electrically coupled to the second electrode and accumulates the signal charges collected by the second electrode.

6. The imaging device according to claim 5, wherein a capacitance value of the first charge accumulator is less than a capacitance value of the second charge accumulator.

7. The imaging device according to claim 1, wherein each of the pixels further includes a capacitor coupled to the second electrode.

8. The imaging device according to claim 1, wherein each of the pixels further includes a charge accumulation electrode that is located between the first transfer gate and the second transfer gate and that faces the counter electrode through the photoelectric conversion layer.

9. The imaging device according to claim 1, wherein each of the pixels further includes a semiconductor layer that is located between the photoelectric conversion layer and each of the first electrode and the second electrode.

10. The imaging device according to claim 9, wherein a charge mobility of the semiconductor layer is greater than a charge mobility of the photoelectric conversion layer.

11. The imaging device according to claim 1, wherein a length of the first readout period is the same as a length of the second readout period.

12. The imaging device according to claim 11, wherein a length of the first readout period is the same as a length of a vertical synchronization period.

13. The imaging device according to claim 1, wherein a length of the second readout period is greater than a length of the first readout period.

14. The imaging device according to claim 1, further comprising
a voltage supply circuit coupled to the counter electrode, wherein
the voltage supply circuit
supplies a first voltage to the counter electrode in the first readout period, and
supplies a second voltage to the counter electrode in the second readout period, the second voltage being different from the first voltage.

15. The imaging device according to claim 14, wherein
the photoelectric conversion layer includes
a first photoelectric conversion layer that is sensitive to light having a first range of wavelength, and
a second photoelectric conversion layer that is sensitive to light having a second range of wavelength that is different from the first range of wavelength.

16. The imaging device according to claim 1, wherein each of the plurality of pixels further includes a first feedback circuit that negatively feeds back a potential of the first electrode to the first electrode.

17. The imaging device according to claim 16, wherein each of the plurality of pixels further includes a second feedback circuit that negatively feeds back a potential of the second electrode to the second electrode.

18. The imaging device according to claim 1, further comprising
a voltage supply circuit, wherein
the voltage supply circuit
supplies a voltage that forms an electric field serving as a barrier against movement of the signal charges to the first electrode, to the first transfer gate in the first readout period,
supplies a voltage that forms an electric field serving as a barrier against movement of the signal charges to the second electrode, to the second transfer gate in the second readout period,
supplies a voltage that forms an electric field allowing the movement of the signal charges to the second electrode, to the second transfer gate in the first period, and
supplies a voltage that forms an electric field allowing the movement of the signal charges to the first electrode, to the first transfer gate in the second period.

19. The imaging device according to claim 4, further comprising
a voltage supply circuit, wherein
the voltage supply circuit
supplies a voltage that forms an electric field serving as a barrier against movement of the signal charges to the first electrode, to the first transfer gate in the first readout period and the fourth period,
supplies a voltage that forms an electric field serving as a barrier against movement of the signal charges to the second electrode, to the second transfer gate in the second readout period and the third period,
supplies a voltage that forms an electric field allowing the movement of the signal charges to the second electrode, to the second transfer gate in the first period, and
supplies a voltage that forms an electric field allowing the movement of the signal charges to the first electrode, to the first transfer gate in the second period.

20. An imaging device comprising:
pixels, each of the pixels including:
a photoelectric conversion layer that converts light into signal charges;
a counter electrode that applies bias voltage to the photoelectric conversion layer;
a first electrode and a second electrode that are spaced from each other and collect the signal charges generated in the photoelectric conversion layer;
a first transfer gate that controls transfer of the signal charges to the first electrode;
a second transfer gate that controls transfer of the signal charges to the second electrode;
a first amplification transistor that includes a first gate electrically coupled to the first electrode;
a second amplification transistor that includes a second gate electrically coupled to the second electrode; and
a voltage supply circuit, wherein
the voltage supply circuit
supplies a voltage that forms an electric field serving as a barrier against movement of the signal charges to the first electrode, to the first transfer gate in a first readout period in which the first amplification transistor outputs a signal corresponding to a potential of the first gate,
supplies a voltage that forms an electric field serving as a barrier against movement of the signal charges to the second electrode, to the second transfer gate in a second readout period in which the second amplification transistor outputs a signal corresponding to a potential of the second gate,
supplies a voltage that forms an electric field allowing the movement of the signal charges to the second electrode, to the second transfer gate in a first period included in the first readout period, and
supplies a voltage that forms an electric field allowing the movement of the signal charges to the first electrode, to the first transfer gate in a second period included in the second readout period.
